(19) United States
(12) Patent Application Publication
(10) Pub. No.: US 2025/0267970 A1
(43) Pub. Date: Aug. 21, 2025

(54) PHOTOELECTRIC CONVERSION APPARATUS

(71) Applicant: CANON KABUSHIKI KAISHA, Tokyo (JP)

(72) Inventor: TOSHIYUKI OGAWA, Chiba (JP)

(21) Appl. No.: 19/047,463

(22) Filed: Feb. 6, 2025

(30) Foreign Application Priority Data
Feb. 16, 2024 (JP) 2024-021764

(51) Int. Cl. H10F 39/00; H10F 39/18

(52) U.S. Cl. CPC H10F 39/807; H10F 39/182; H10F 39/8063

(57) ABSTRACT

A photoelectric conversion apparatus includes a semiconductor substrate having first and second principal surfaces, a microlens array, pixels each including a corresponding one microlens, photoelectric conversion units in rows and columns that is arranged inside the semiconductor substrate, and arranged in such a manner as to corresponding to the one microlens, and a first trench portion that separates photoelectric conversion units, and a second trench portion provided between neighboring two pixels, wherein, a first region between one first portion and other first portion and a second region between one second portion and other second portion each include a semiconductor region, and wherein, at a depth position between the first principal surface and the second principal surface, in the planar view, a part of the first trench portion is arranged at each of a position overlapping the first region and a position overlapping the second region.

### BACKGROUND OF THE INVENTION

### Field of the Invention

The present disclosure relates to a photoelectric conversion apparatus that converts light into an electric signal.

### Description of the Related Art

There has been known a photoelectric conversion apparatus that generates a signal charge corresponding to incident light.

A configuration in which a trench portion is provided between a plurality of photoelectric conversion units as discussed in United States Patent Application Publication No. 2016/0056200 has been known as the photoelectric conversion apparatus. By providing this trench portion, it is possible to desirably electrically separate the plurality of photoelectric conversion units.

### SUMMARY OF THE INVENTION

According to an aspect of the present disclosure, a photoelectric conversion apparatus includes a semiconductor substrate having a first principal surface from which light enters, and a second principal surface facing the first principal surface, a microlens array including a plurality of microlenses, a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, and a first trench portion that separates the plurality of photoelectric conversion units, and a second trench portion provided between a photoelectric conversion unit included in one pixel of neighboring two pixels among the plurality of pixels, and a photoelectric conversion unit included in other one pixel of the neighboring two pixels, wherein, on the first principal surface, in a planar view with respect to the first principal surface, the first trench portion includes a plurality of first portions extending in a first direction, and a plurality of second portions extending in a second direction intersecting with the first direction, wherein a first region between one first portion and other first portion of the plurality of first portions, and a second region between one second portion and other second portion of the plurality of second portions each include a semiconductor region of the semiconductor substrate, and wherein, at a depth position between the first principal surface and the second principal surface, in the planar view, a part of the first trench portion is arranged at each of a position overlapping the first region and a position overlapping the second region.

According to another aspect, a photoelectric conversion apparatus includes a semiconductor substrate having a first principal surface from which light enters, and a second principal surface facing the first principal surface, a microlens array including a plurality of microlenses, a microlens array including a plurality of microlenses, a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, a first trench portion that separates the plurality of photoelectric conversion units, and a plurality of amplification transistors each having a gate, and a second trench portion provided between a photoelectric conversion unit included in one pixel of neighboring two pixels among the plurality of pixels, and a photoelectric conversion unit included in other one pixel of the neighboring two pixels, wherein the respective gates of the plurality of amplification transistors are connected in common to a node to which signal charges of the plurality of photoelectric conversion units are input, wherein, on the second principal surface, in a planar view with respect to the second principal surface, the first trench portion includes a plurality of first portions extending in a first direction, and a plurality of second portions extending in a second direction intersecting with the first direction, wherein a first region between one first portion and other first portion of the plurality of first portions, and a second region between one second portion and other second portion of the plurality of second portions each include a semiconductor region of the semiconductor substrate, and wherein, at a depth position between the first principal surface and the second principal surface, in the planar view, a part of the first trench portion is arranged at each of a position overlapping the first region and a position overlapping the second region.

According to still another aspect, a photoelectric conversion apparatus includes a semiconductor substrate having a first principal surface from which light enters, and a second principal surface facing the first principal surface, a microlens array including a plurality of microlenses, a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, and a first trench portion that separates the plurality of photoelectric conversion units, and a second trench portion provided between a photoelectric conversion unit included in one pixel of neighboring two pixels among the plurality of pixels, and a photoelectric conversion unit included in other one pixel of the neighboring two pixels, wherein, on the first principal surface, in a planar view with respect to the first principal surface, the first trench portion includes a first portion extending in a first direction, wherein, on the second principal surface, in a planar view with respect to the second principal surface, the first trench portion includes a third portion extending in the first direction, wherein the first portion and the third portion have portions overlapping in the planar view with respect to the first principal surface, and wherein a semiconductor region of the semiconductor substrate is arranged between the first portion and the third portion.

Further features of the present invention will become apparent from the following description of exemplary embodiments with reference to the attached drawings.

### BRIEF DESCRIPTION OF THE DRAWINGS

FIG. 1 is a block diagram illustrating an overall configuration of a photoelectric conversion apparatus.

FIG. 2 is a diagram illustrating a configuration of a unit.

FIG. 3 is a diagram illustrating a configuration of a unit.

FIG. 4 is a block diagram illustrating a partial configuration of a photoelectric conversion apparatus.

FIG. 5 is a drive timing chart illustrating an operation of a photoelectric conversion apparatus.

FIG. 6 is a diagram illustrating a configuration of a stack-type photoelectric conversion apparatus.

FIG. 7 is a plan view of a photoelectric conversion apparatus.

FIG. 8 is a cross-sectional view of a photoelectric conversion apparatus.

FIG. 9 is a cross-sectional view of a photoelectric conversion apparatus.

FIG. 10 is a cross-sectional view of a photoelectric conversion apparatus.

FIG. 11 is a cross-sectional view of a photoelectric conversion apparatus.

FIG. 12 is a plan view of a photoelectric conversion apparatus.

FIG. 13 is a cross-sectional view of a photoelectric conversion apparatus.

FIG. 14 is a plan view of a photoelectric conversion apparatus.

FIG. 15 is a cross-sectional view of a photoelectric conversion apparatus.

FIG. 16 is a cross-sectional view of a photoelectric conversion apparatus.

FIG. 17 is a cross-sectional view of a photoelectric conversion apparatus.

FIG. 18 is a cross-sectional view of a photoelectric conversion apparatus.

FIG. 19 is a plan view of a photoelectric conversion apparatus.

FIG. 20 is a cross-sectional view of a photoelectric conversion apparatus.

FIGS. 21A and 21B are plan views of a photoelectric conversion apparatus.

FIG. 22 is a plan view of a photoelectric conversion apparatus.

FIG. 23 is a cross-sectional view of a photoelectric conversion apparatus.

FIG. 24 is a cross-sectional view of a photoelectric conversion apparatus.

FIG. 25 is a cross-sectional view of a photoelectric conversion apparatus.

FIG. 26 is a cross-sectional view of a photoelectric conversion apparatus.

FIG. 27 is a plan view of a photoelectric conversion apparatus.

FIGS. 28A, 28B, and 28C are diagrams illustrating a configuration of a device.

### DESCRIPTION OF THE EMBODIMENTS

In the technique discussed in United States Patent Application Publication No. 2016/0056200, the consideration of a structure of a desirable trench portion in a configuration in which a plurality of photoelectric conversion units is provided for one microlens has been insufficient.

A technique of the present disclosure provides a structure of a desirable trench portion in a configuration in which a plurality of photoelectric conversion units is provided for one microlens.

Hereinafter, each exemplary embodiment will be described with reference to the drawings.

In each exemplary embodiment to be described below, an imaging apparatus will be mainly described as an example of a photoelectric conversion apparatus. Nevertheless, each exemplary embodiment is not limited to the imaging apparatus and can be applied to another example of the photoelectric conversion apparatus. Examples of the photoelectric conversion apparatus include a distance measurement apparatus (apparatus for distance measurement that uses focus detection or time of flight (TOF)), and a photometric apparatus (apparatus for measurement of an incident light amount).

Conductivity types of semiconductor regions and wells, and dopants to be implanted, which will be described below in the following exemplary embodiments, are mere examples. The conductivity types and the dopants are not limited to those described in the exemplary embodiments. The conductivity types and the dopants can be appropriately changed from those described in the exemplary embodiments, and the potentials of semiconductor regions and wells are appropriately changed in accordance with the change.

The conductivity type of a transistor to be described in the following exemplary embodiments is a mere example, and the conductivity type is not limited to the conductivity type described in the exemplary embodiments. The conductivity type can be appropriately changed from the conductivity type described in the exemplary embodiments, and potentials of a gate, a source, and a drain of the transistor are appropriately changed in accordance with the change.

For example, as for a transistor to be operated as a switch, it is sufficient that a low level and a high level of a potential to be supplied to a gate are made reverse to those described in the exemplary embodiments, in accordance with the change of a conductivity type. In addition, the conductivity type of a semiconductor region to be described in the following exemplary embodiments is a mere example, and the conductivity type is not limited to the conductivity type described in the exemplary embodiments. The conductivity type can be appropriately changed from the conductivity type described in the exemplary embodiments, and the potential of the semiconductor region is appropriately changed in accordance with the change.

In the following exemplary embodiments, the connection between elements of circuits will be sometimes described. In this case, even in a case where another element is interposed between elements to be observed, unless otherwise noted, the elements to be observed are treated as being connected. For example, it is assumed that an element A is connected to one node of a capacitative element C having a plurality of nodes, and an element B is connected to the other node. Even in such a case, unless otherwise noted, the elements A and B are treated as being connected.

A metal member such as a wire and a pad to be described in this specification may be a metal body of a certain single element, or may be a mixture (alloy). For example, a wire to be described as a copper wire may be a copper single body, or may have a configuration mainly containing copper and further containing other components. In addition, for example, a pad to be connected with an external terminal may be an aluminum single body, or may have a configuration mainly containing aluminum and further containing other components. The copper wire and the aluminum pad described here are examples, and can be changed to various types of metal.

The wire and the pad described here are examples of metal members to be used in a photoelectric conversion apparatus, and can also be applied to other metal members.

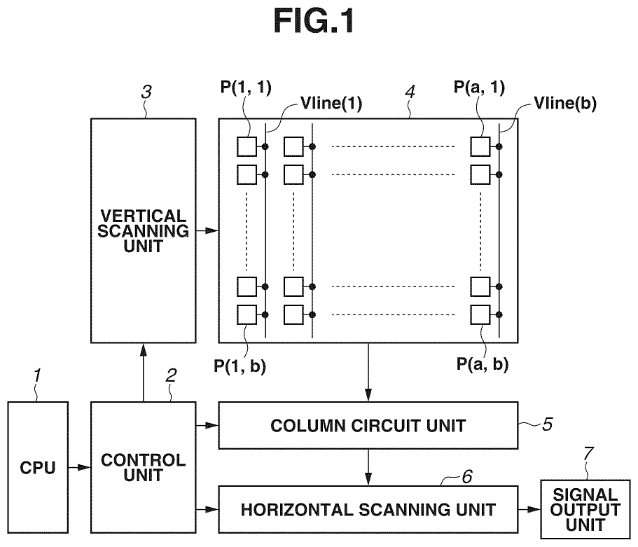

FIG. 1 is a block diagram illustrating a schematic configuration of a photoelectric conversion apparatus according to a first exemplary embodiment. The photoelectric conversion apparatus includes a central processing unit (CPU) 1, a control unit 2, a vertical scanning unit 3, a pixel array 4, a column circuit unit 5, a horizontal scanning unit 406, and a signal output unit 7.

Various circuits included in the photoelectric conversion apparatus can be formed on one or a plurality of semiconductor substrates.

The CPU 1 is a processor that controls the photoelectric conversion apparatus by executing a program. The CPU 1 may be provided within the photoelectric conversion apparatus, or may be provided within a photoelectric conversion system in which the photoelectric conversion apparatus is mounted (i.e., may be provided outside the photoelectric conversion apparatus).

The control unit 2 is a control circuit that supplies a control signal to the vertical scanning unit 3, the column circuit unit 5, and the horizontal scanning unit 406 upon receiving a control signal such as a synchronization signal and a setting signal indicating an operation mode that are output from the CPU 1.

The vertical scanning unit 3 is a scanning circuit including a shift register, a gate circuit, and a buffer circuit. The vertical scanning unit 3 performs reset scanning and readout scanning of the pixel array 4 upon receiving control signals such as a vertical synchronization signal, a horizontal synchronization signal, and a clock signal from the control unit 2. The reset scanning refers to an operation of starting exposure by sequentially cancelling a reset state of the photoelectric conversion units and bringing the photoelectric conversion units into a charge accumulation state for pixels on a part or all of rows of the pixel array 4. In addition, the readout scanning refers to an operation of sequentially outputting signals that are based on the charges accumulated in the photoelectric conversion units, to pixels on a part or all of rows of the pixel array 4. The vertical scanning unit 3 corresponds to a drive device that outputs a drive signal for driving the pixel array 4 for each row, to the pixel array 4.

The pixel array 4 includes a plurality of pixels P(1, 1) to P(a, b) on N rows and M columns that are arrayed on a plurality of rows and a plurality of columns, and a plurality of vertical output lines Vline(1) to Vline(b) on the M columns. Here, a row direction refers to a horizontal direction in the drawings, and a column direction refers to a vertical direction in the drawings. In addition, numbers in the parenthesis of the pixel P(a, b) sequentially indicates a column number and a row number. A row number of the uppermost row in FIG. 1 is 1, and a column number of the leftmost column in FIG. 1 is 1. In a case where there is no need to indicate a column number and a row number, numbers indicating a column number and a row number are sometimes omitted.

The column circuit unit 5 includes an amplification circuit, an analog-to-digital conversion (hereinafter, will be described as “AD conversion”.) circuit, and a column memory. These circuits are arranged corresponding to each of the vertical output lines Vline(1) to Vline(b). The column circuit unit 5 amplifies a signal read out from the pixel array 4, performs AD conversion, and stores the signal into the column memory as a digital signal. The horizontal scanning unit 406 is a scanning circuit including a shift register, a gate circuit, and a buffer circuit. Upon receiving a control signal from the control unit 2, the horizontal scanning unit 406 sequentially scans signals stored in the memory of the column circuit unit 5, and outputs the signals to the signal output unit 7.

The signal output unit 7 includes a digital processing unit and an output circuit such as a parallel-serial conversion circuit or low voltage differential signaling (LVDS). The signal output unit 7 performs digital processing of a signal output from the horizontal scanning unit 406, and outputs the processed signal to the outside of the photoelectric conversion apparatus as serial data.

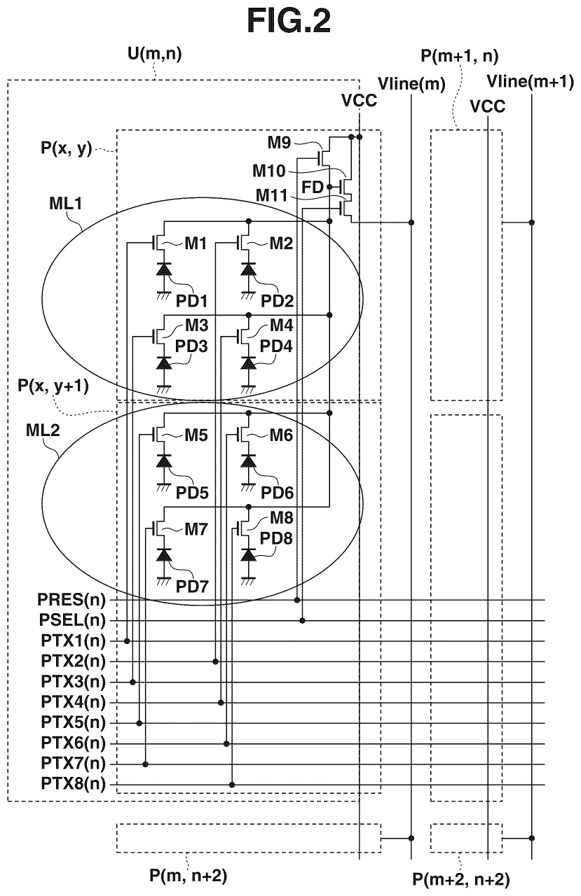

The column circuit unit 5 needs not always include the function of AD conversion, and a configuration may be modified in such a manner that AD conversion is performed on the outside of the photoelectric conversion apparatus, for example. In this case, the configurations of the horizontal scanning unit 406 and the signal output unit 7 are also appropriately modified in such manner as to be adapted to the processing of an analog signal. FIG. 2 is a circuit diagram of a pixel P included in the pixel array 4 according to the present exemplary embodiment. FIG. 2 illustrates a configuration of a pixel P(x, y) on an x-th column and a y-th row, a pixel P(x, y+1) on the x-th column and a (y+1)th row.

A unit U (m, n) includes the pixels P in two rows. The unit U (m, n) illustrated in FIG. 2 includes the pixel P(x, y) and the pixel P(x, y+1).

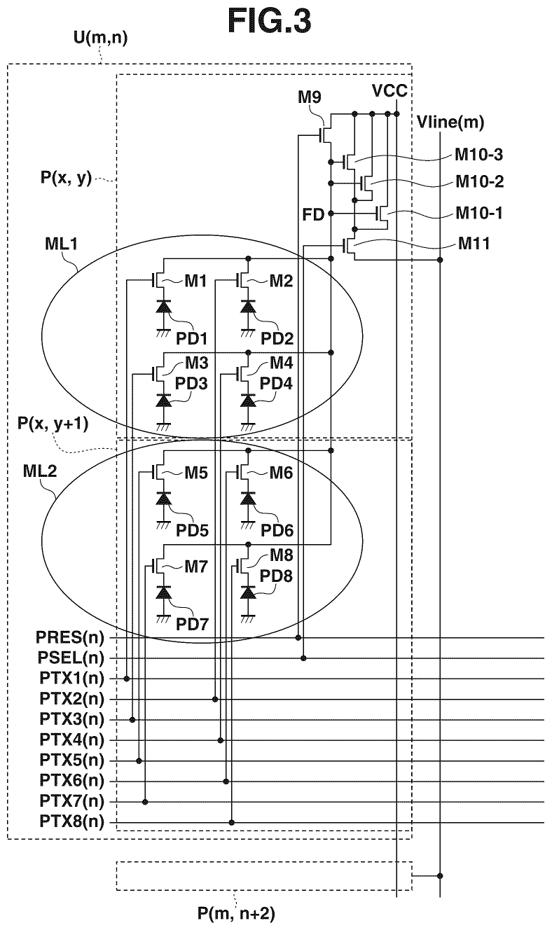

Each unit U includes photoelectric conversion units PD1 to PD8, a floating diffusion FD, transfer transistors M1 to M8, a reset transistor M9, an amplification transistor M10, and a selection transistor M11. In the unit U, the eight photoelectric conversion units PD1 to PD8 share the one floating diffusion FD. FIG. 2 illustrates a configuration in which the one amplification transistor M10 is provided for one unit U. Alternatively, a configuration in which a plurality of amplification transistors M10-1, M10-2, and M10-3 are provided as illustrated in FIG. 3 may be employed, and the number of amplification transistors is not limited.

Each of the photoelectric conversion units PD1 to PD8 is a photoelectric conversion element that generates and accumulates charges corresponding to incident light, by photoelectrically-converting the incident light. Each of the photoelectric conversion units PD1 to PD8 is a photodiode, for example. An anode of the photodiode included in each of the photoelectric conversion units PD1 to PD8 is connected to a node of a ground potential. Cathodes of photodiodes included in the respective photoelectric conversion units PD1 to PD8 are connected to sources of the respective transfer transistors M1 to M8. FIG. 2 illustrates a configuration in which the eight photoelectric conversion units PD1 to PD8 share the one floating diffusion FD, but the configuration is not limited to this example. One floating diffusion FD may be arranged in such a manner as to correspond to one photoelectric conversion unit PD1, or one floating diffusion FD may be arranged in such a manner as to correspond to the four photoelectric conversion units PD1 to PD4.

Drains of the transfer transistors M1 to M8 are connected to the floating diffusion FD serving as a connection node of a source of the reset transistor M9 and a gate of the amplification transistor M10. A drain of the reset transistor M9 and a drain of the amplification transistor M10 are electrically connected to a power line having a pixel power potential VCC. A source of the amplification transistor M10 is connected to a drain of the selection transistor M11. A source of the selection transistor M11 is electrically connected to a current source (not illustrated) via a vertical output line Vline(m). The amplification transistor M10 and the current source accordingly operate as a source follower circuit. That is, the amplification transistor M10 functions as an output unit that can output a signal corresponding to the potential of the floating diffusion FD, to the vertical output line Vline(m). The floating diffusion FD contains a capacitive component (floating diffusion capacitance), and functions as a charge holding unit due to the capacitive component.

Control signals PTX1(n) to PTX8(n) are respectively input to gates of the transfer transistors M1 to M8 from the vertical scanning unit 3. The transfer transistors M1 to M8 transfer charges accumulated in the photoelectric conversion units PD1 to PD8, to the floating diffusion FD based on the respective control signals PTX1(n) to PTX8(n). That is, each of the transfer transistors M1 to M8 functions as a charge transfer unit. The floating diffusion FD holds transferred charges.

A control signal PRES (n) is input to a gate of the reset transistor M9 from the vertical scanning unit 3. The reset transistor M9 resets the potential of the floating diffusion FD to a predetermined potential based on the control signal PRES (n).

A control signal PSEL(n) is input to a gate of the selection transistor M11 from the vertical scanning unit 3. The control signal PSEL(n) is a signal for selecting a row to which a signal is to be output, and the selection transistor M11 enters a conductive state or non-conductive state based on the control signal PSEL(n). An additional character “n” of each control signal indicates a row number of a corresponding row.

A transistor is assumed to enter the conductive state when a control signal input to a gate is at a high level, and enters the non-conductive state when the control signal is at a low level. In addition, the high level corresponds to a logical value “1” and the low level corresponds to a logical value “0”.

When the transfer transistors M1 to M8 are in the non-conductive state, the photoelectric conversion units PD1 to PD8 enter an accumulation state of accumulating charges generated by photoelectric conversion. When the transfer transistors M1 to M8 are in the conductive state and the reset transistor M9 is in the conductive state, the photoelectric conversion units PD1 to PD8 enter a non-accumulation state in which charges are not accumulated (i.e., reset state). When any of the transfer transistors M1 to M8 is in the conductive state and the reset transistor M9 is in the non-conductive state, the pixel P(m, n) enters a readout state in which charges of the photoelectric conversion units PD1 to PD8 can be read out by transferring the charges to the floating diffusion FD. The reset of the photoelectric conversion units PD1 to PD8 may be controlled by a charge discharge transistor configured to electrically connect cathodes of the photoelectric conversion units PD1 to PD8 to a power line having a power potential.

In the present exemplary embodiment, each transistor is assumed to be an N-channel metal-oxide semiconductor (MOS) transistor, but may be a P-channel MOS transistor. In this case, the level of each control signal can be appropriately changed.

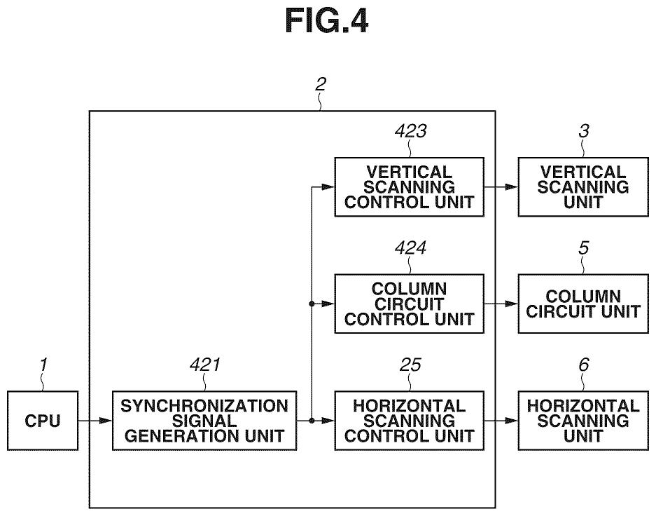

FIG. 4 is a block diagram illustrating a configuration of the control unit 2 according to the present exemplary embodiment. The control unit 2 includes a synchronization signal generation unit 421, a vertical scanning control unit 423, a column circuit control unit 424, and a horizontal scanning control unit 25.

In accordance with the control of the CPU 1, the synchronization signal generation unit 421 generates a vertical synchronization signal and a horizontal synchronization signal to be used for the control of an operation timing of each component for readout scanning and reset scanning.

The vertical scanning control unit 423 generates a control signal for controlling the drive of the vertical scanning unit 3, and outputs the generated control signal to the vertical scanning unit 3. In accordance with a control signal from the vertical scanning control unit 423, the vertical scanning unit 3 outputs a control signal RES, a control signal SEL, and control signals TX1 to TX8. In some cases, an additional character indicating a row number is added to the control signals. Hereinafter, control signals to be output from the vertical scanning unit 3 will be collectively referred to as pixel drive pulses.

The column circuit control unit 424 generates a control signal for controlling the drive of the column circuit unit 5, and outputs the generated control signal to the column circuit unit 5. The horizontal scanning control unit 25 generates a control signal for controlling the drive of the horizontal scanning unit 6, and outputs the generated control signal to the horizontal scanning unit 6.

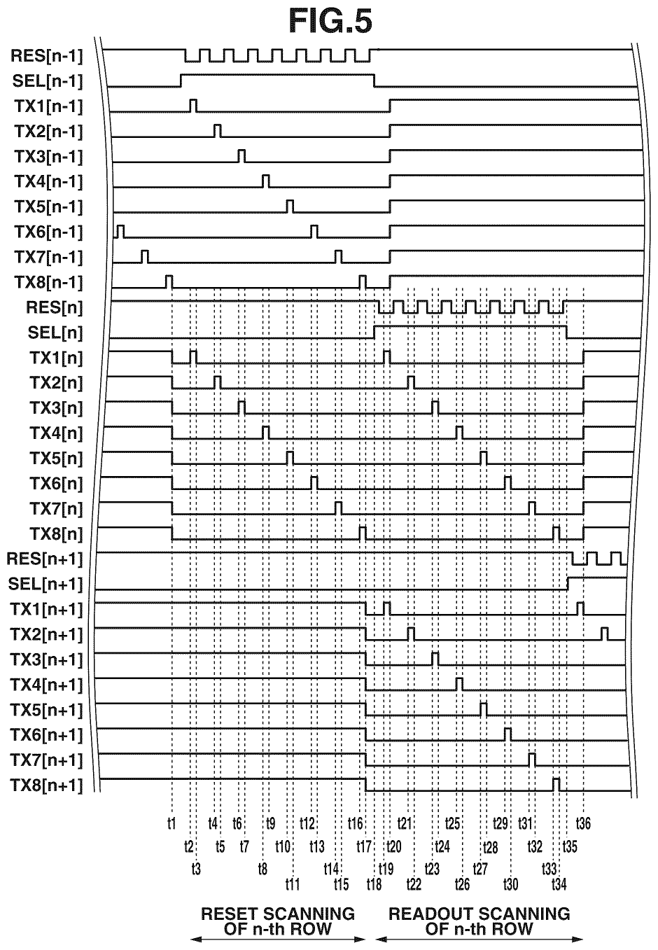

Next, a pixel drive pulse to be output from the vertical scanning unit 3 will be described with reference to FIG. 5. FIG. 5 is a timing chart of a control signal to be output from the vertical scanning unit 3 according to the present exemplary embodiment. FIG. 5 selectively illustrates timings of pixel drive pulses corresponding to the pixels P of three rows including an (n−1)-th row, an n-th row, and an (n+1)-th row. Because the timings of pixel drive pulses of the (n−1)-th row and the (n+1)-th row are merely shifted in a time direction with respect to the timing of the n-th row, hereinafter, pixel drive pulses of the n-th row will be described, and the description of the other rows will be omitted.

In a period anterior to a time t1, the control signal RES[n] and the control signals TX1[n] to TX8[n] are maintained at the high level. The photoelectric conversion units PD1 to PD8 are accordingly maintained in the reset state. In addition, the control signal SEL [n] is maintained at the low level and the selection transistor M11 is in the non-conductive state.

At the time t1, the control signals TX1[n] to TX8[n] transition to the low level. The reset state of the photoelectric conversion units PD1 to PD8 is thereby cancelled.

At a time t2, the control signal TX1[n] transitions to the high level, and the photoelectric conversion unit to which the control signal TX1[n] is input is once reset. After that, at the time t3, the control signal TX1[n] transitions to the low level. By these operations, charge accumulation is started in the photoelectric conversion unit to which the control signal TX1[n] is input.

At a time t4, the control signal TX2[n] transitions to the high level, and the photoelectric conversion unit to which the control signal TX2[n] is input is once reset. After that, at the time t5, the control signal TX2[n] transitions to the low level. By these operations, charge accumulation is started in the photoelectric conversion unit to which the control signal TX2[n] is input.

During a period from a time t6 to a time t17, pulses of the control signals TX3[n] to TX8[n] are similarly output, and accumulation in the photoelectric conversion units is sequentially started. A series of operations from the time t2 to a time t17 is called reset scanning of the n-th row.

The length of a period from a time t17 immediately after the reset scanning of the n-th row, to a time t18 at which the next operation starts can be appropriately set. By adjusting the length of this period, it is possible to control the charge accumulation time of the photoelectric conversion units PD1 to PD8. The setting of the length of the period is made based on a control signal from the CPU 1, for example. FIG. 5 illustrates a case where the length of the period from the time t17 to the time t18 is the shortest.

At the time t18, the control signal SEL [n] transitions to the high level, and the selection transistor M11 enters the conductive state. The amplification transistor M10 of the pixel P(m, n) and the vertical output line Vline(m) are thereby electrically connected via the selection transistor M11.

By this operation, a state in which a signal that is based on the potential of the floating diffusion FD can be output to the vertical output line Vline(m) of an m-th column is caused.

During a time from the time t18 to a time t19, the control signal RES[n] transitions to the low level. The reset state of the floating diffusion FD is accordingly cancelled.

After the reset of the floating diffusion FD is cancelled, at the time t19, the control signal TX1[n] transitions to the high level. By this operation, charges accumulated in the photoelectric conversion unit to which the control signal TX1[n] is input are transferred to the floating diffusion FD. Then, a signal corresponding to the potential of the floating diffusion FD is output to the vertical output line Vline(m) on the m-th column. The signal output to the vertical output line Vline(m) is amplified and AD-converted in the column circuit unit 5, and then stored into the column memory as a digital signal.

After that, at a time t20, the control signal TX1[n] transitions to the low level. A transfer operation of charges accumulated in the photoelectric conversion unit is thereby completed. That is, a period from the time t3 to the time t20 corresponds to a charge accumulation period in the photoelectric conversion unit.

During a time from the time t20 to a time t21, the control signal RES[n] transitions to the high level, and after a predetermined time, transitions again to the low level. By this operation, the potential of the floating diffusion FD is reset.

At the time t21, the control signal TX2[n] transitions to the high level, and a transfer operation similar to that at the time t19 starts. After that, at a time t22, the control signal TX2[n] transitions to the low level, and a transfer operation of charges accumulated in the photoelectric conversion unit is completed.

During a period from a time t23 to a time t34, pulses of the control signals TX3[n] to TX8[n] are similarly output, and a transfer operation from the photoelectric conversion units to the floating diffusion FD is sequentially performed. A series of operations from the time t19 to a time t34 is called readout scanning of the n-th row.

At a time t35, the control signal SEL [n] transitions to the low level, and the selection transistor M11 enters the non-conductive state. Accordingly, the amplification transistor M10 of the pixel P and the vertical output line Vline(m) become electrically-disconnected.

At a time t36, the control signals TX1[n] to TX8[n] transition to the high level.

The photoelectric conversion units PD1 to PD8 accordingly enter the reset state. In the above-described manner, a series of operations from a charge accumulation start in the unit U on the n-th row to an end of the readout scanning of the n-th row are completed.

In this example, an operation of reading out signal charges one by one from the photoelectric conversion units PD1 to PD8 by individually controlling the control signals TX1[n] to TX8[n] has been described, but the operation is not limited to this operation.

For example, in the case of performing focus detection focused on a longitudinal direction of a subject, signals may be simultaneously read out from photoelectric conversion units PD neighboring in the row direction. In other words, the control signal TX1[n] and the control signal TX3[n] may be synchronized, and the control signal TX2[n] and the control signal TX4[n] may be synchronized. Alternatively, in the case of performing focus detection focused on a traverse direction of a subject, the control signal TX1[n] and the control signal TX2[n] may be synchronized, and the control signal TX3[n] and the control signal TX4[n] may be synchronized.

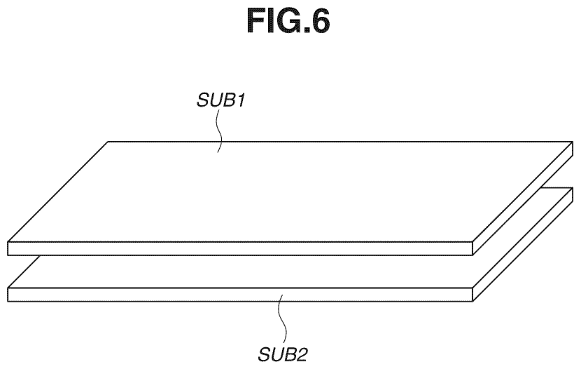

FIG. 6 is a configuration diagram of a photoelectric conversion apparatus according to the present exemplary embodiment. The photoelectric conversion apparatus according to the present exemplary embodiment has a structure of a stacked sensor in which a first substrate SUB1, which is a semiconductor substrate, and a second substrate SUB2 are stacked. The first substrate SUB1 is typically formed using a silicon single crystal. The second substrate SUB2 may also be formed using a silicon single crystal. Nevertheless, the material is not limited to this example, and the first substrate SUB1 and the second substrate SUB2 may be compound semiconductor substrates obtained by combining a plurality of materials. In other words, the first substrate SUB1 and the second substrate SUB2 can be various semiconductor substrates.

In addition, the arrangement of the members illustrated in FIG. 1, on the first substrate SUB1 and the second substrate SUB2 can be appropriately changed.

In addition, the photoelectric conversion apparatus according to the present exemplary embodiment is not limited to the stacked sensor. In other words, the photoelectric conversion apparatus according to the present exemplary embodiment may be a back-illuminated non-stacked sensor in which the second substrate SUB2 is used as a support substrate and all the members illustrated in FIG. 1 are arranged on the first substrate SUB1.

The pixel array 4 illustrated in FIG. 1 are arranged on the first substrate SUB1. On the other hand, among the components illustrated in FIG. 1, members other than the pixel array 4 are arranged on the second substrate SUB2. Electrical connection between the first substrate SUB1 and the second substrate SUB2 can be established using a known method. For example, a via structure including a metal portion penetrating through the first substrate SUB1 may be provided, and the via structure may connect a wire existing between the first substrate SUB1 and a bonded surface with a wire existing between the second substrate SUB2 and a bonded surface. This connection method is sometimes called through silicon via (TSV). As another configuration, an exposed metal bonding portion is provided inside an insulating film on the bonded surface on the side of the first substrate SUB1. This metal bonding portion is connected to the wire between the first substrate SUB1 and the bonded surface. In a similar manner, an exposed metal bonding portion is provided inside an insulating film on the bonded surface on the side of the second substrate SUB2. This metal bonding portion is connected to the wire between the second substrate SUB2 and the bonded surface. The metal bonding portions and the insulating films that are respectively provided on the bonded surface on the side of the first substrate SUB1 and the bonded surface on the side of the second substrate SUB2 are bonded. This can electrically connect the wire between the first substrate SUB1 and the bonded surface, and the wire between the second substrate SUB2 and the bonded surface. This connection method is sometimes called hybrid bonding.

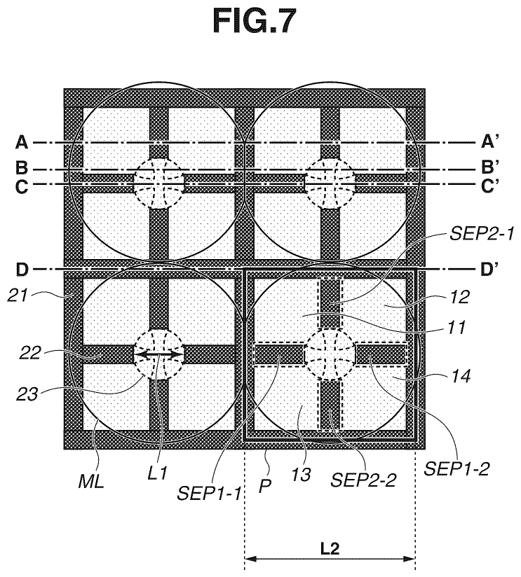

FIG. 7 is a plan view illustrating a structure of the pixel P according to the present exemplary embodiment. This plan view is a planar view with respect to a first principal surface of the first substrate SUB1, which is a principal surface from which light enters.

The pixel P includes N-type semiconductor regions 11 to 14 that are respectively included in the photoelectric conversion units PD1 to PD4. The photoelectric conversion unit PD1 illustrated in FIG. 3 includes the semiconductor region 11. In a similar manner, the photoelectric conversion units PD2, PD3, and PD4 respectively include the semiconductor region 12, the semiconductor region 13, and the semiconductor region 14 in this order. In addition, the pixel P includes a trench portion 22 as a first trench portion that is an isolation portion in the pixel that electrically separates the N-type semiconductor regions 11 to 14. In a planar view with respect to the first principal surface, the trench portion 22 includes a plurality of first portions SEP1-1 and SEP1-2 extending in a first direction, which is the row direction, and a plurality of second portions SEP2-1 and SEP2-2 extending in a second direction, which is the column direction.

The first direction and the second direction are directions intersecting with each other. On the first principal surface, a semiconductor region 23 of the first substrate SUB1, which is a semiconductor substrate, is provided in a first region between the first portions SEP1-1 and SEP1-2, and in a second region between the second portions SEP2-1 and SEP2-2. In the present exemplary embodiment, the first region and the second region can be considered as the same region. The first region is a region between one and the other of a plurality of first portions SEP1-1 and SEP1-2. The second region is a region between one and the other of a plurality of second portions SEP2-1 and SEP2-2.

In a planar view with respect to the first principal surface, a part of the trench portion 22 provided inside the first substrate SUB1 is provided at a position overlapping the semiconductor region 23. The semiconductor region 23 serves as a pathway on which charges move from one N-type semiconductor region to the other N-type semiconductor region of a plurality of N-type semiconductor regions 11 to 14.

With this configuration, even in a case where a large amount of charges are generated inside some of the semiconductor regions 11 to 14 to which high-brightness light enters, among the plurality of N-type semiconductor regions 11 to 14, charges can be moved to the other semiconductor regions 11 to 14. With this configuration, because charges corresponding to incident light can be accumulated using a plurality of semiconductor regions 11 to 14, it is possible to expand a dynamic range on a high brightness side. In particular, it is possible to expand a dynamic range on a high brightness side while suppressing a deterioration in linearity of an output signal of the pixel P with respect to an incident light amount.

Because the semiconductor region 23 is a moving pathway of charges generated by the plurality of semiconductor regions 11 to 14, the conductivity type of the semiconductor region 23 is desirably set to the same conductivity type as the conductivity type of the plurality of semiconductor regions 11 to 14.

A semiconductor region with a conductivity type different from the conductivity type of the semiconductor regions 11 to 14 may be provided between the semiconductor region 23 and the trench portion 22. In other words, among conductivity types described in the present exemplary embodiment, a P-type semiconductor region may be provided. This P-type semiconductor region has a role of reducing inflow of dark current components generated by the trench portion 22, into the semiconductor regions 11 to 14.

A trench portion 21 is provided between a plurality of pixels P as a second trench portion being an isolation portion between one pixel and the other pixel. The trench portion 21 includes a portion extending in the first direction, which is the row direction, and a portion extending in the second direction, which is the column direction, in a planar view with respect to the first principal surface. The trench portion 21 extends over pixels P of a plurality of rows and a plurality of columns in a planar view with respect to the first principal surface.

A microlens ML is arranged at a position overlapping the N-type semiconductor regions 11 to 14 arranged in two rows and two columns in one pixel P, in a planar view with respect to the first principal surface. The photoelectric conversion apparatus includes a microlens array in which the microlenses ML are arranged respectively corresponding to a plurality of pixels P. Light having passed through one microlens ML enters the four N-type semiconductor regions 11 to 14. By having this configuration, it is possible to individually acquire a signal that is based on a light amount of light that has entered each of the photoelectric conversion units PD1 to PD4, by the drive of the timing chart illustrated in FIG. 5. It is possible to acquire a phase difference component in the row direction and a phase difference component in the column direction. With this configuration, it is possible to perform focus detection focused on the longitudinal direction of the subject, and focus detection focused on the traverse direction.

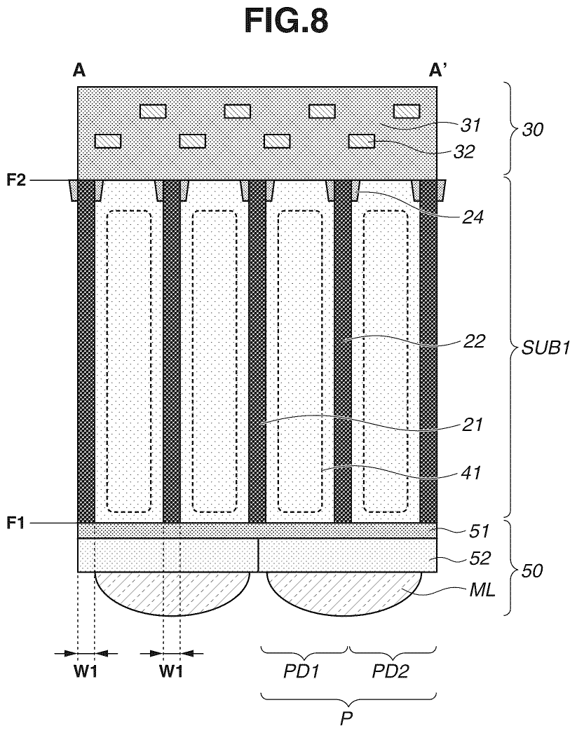

Next, FIG. 8 illustrates a cross-sectional view taken along a line A-A′ illustrated in FIG. 7.

Among members illustrated in FIG. 8, the same members as the members illustrated in FIG. 7 are assigned the same reference numerals as those used in FIG. 7. The first substrate SUB1 has a first principal surface F1, which is a first principal surface from which light enters, and a second principal surface F2, which is a principal surface facing the first principal surface F1. An insulating film 31 is provided on the second principal surface F2. A wiring layer 30 including a wire 32 is provided in the insulating film 31. The second principal surface F2 also serves as a surface on which a gate electrode of each transistor illustrated in FIG. 3 is provided, which is not illustrated in FIG. 8.

A color filter 52 and an insulating film 51 are provided between the first principal surface F1 and the microlens ML. An optical layer 50 includes the microlens ML, the color filter 52, and the insulating film 51.

In a cross-sectional view at a position passing through the line A-A′ illustrated in FIG. 7, the trench portion 21 and the trench portion 22 both extend from one surface to the other surface of the first principal surface F1 and the second principal surface F2 of the first substrate SUB1 in a depth direction of the first substrate SUB1. The trench portion 21 and the trench portion 22 are both in contact with an element isolation portion 24 on the side of the second principal surface F2. The element isolation portion 24 has a structure also called a shallow trench isolation (STI). This STI can be created by a known manufacturing method. Then, by performing etching processing from the formed element isolation portion 24, a hole portion is formed up to the depth of the first principal surface F1. Then, by filling this hole portion with an insulating material, a metal material, or polysilicon, it is possible to form the trench portions 21 and 22. On a side wall of the trench portion 21 or 22, a pinning film may be provided as a single-layer aluminum oxide film or tantalum oxide film, or a film stack obtained by combining films. In the present exemplary embodiment, the trench portions 21 and the trench portion 22 have a structure of a deep trench isolation (DTI) formed from the second principal surface F2 toward the first principal surface F1. In the cross section illustrated in FIG. 8, the trench portions 21 and the trench portion 22 are formed with the same width W1. In FIG. 8, the trench portions 21 and 22 both extend from the second principal surface F2 to the first principal surface F1 with the same width, but the configuration is not limited to this configuration. Both the trench portions 21 and 22 can be formed to become thinner toward the first principal surface F1.

A length L1 in the first direction of the semiconductor region 23 is desirably set to a length equal to or smaller than a half of a length L2 in the first direction of the pixel P. For example, if the length L2 of the pixel P is 1 μm, the length L1 in the first direction of the semiconductor region 23 is set to 0.5 μm or less. With this configuration, it is possible to achieve at least one of electric separation and optical separation of the photoelectric conversion units PD1 to PD4, and the efficiency of charge movement to other photoelectric conversion units PD in a case where a part of photoelectric conversion unit PD of the photoelectric conversion units PD1 to PD4 is saturated.

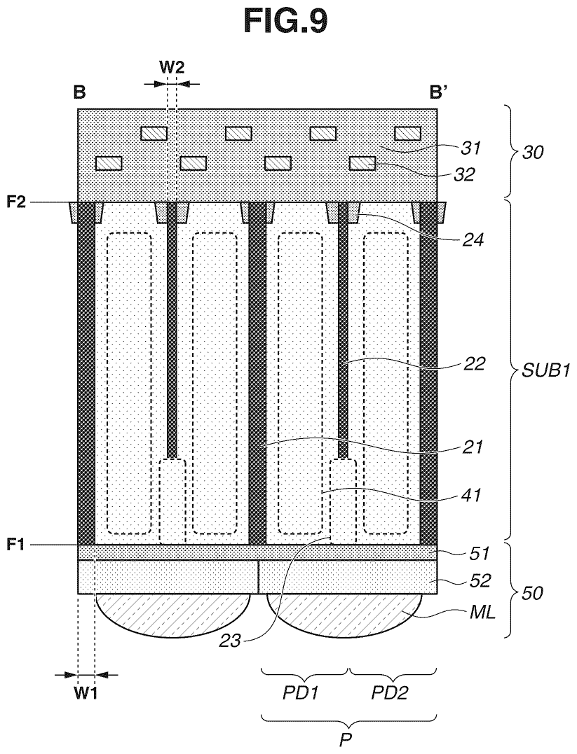

Next, FIG. 9 illustrates a cross-sectional view taken along a line B-B′ illustrated in FIG. 7. Among members illustrated in FIG. 9, the same members as the members illustrated in FIGS. 7 and 8 are assigned the same reference numerals as those used in FIGS. 7 and 8.

In the cross-sectional view illustrated in FIG. 9, a bottom portion of the trench portion 22 has contact with the semiconductor region 23. In other words, the bottom portion of the trench portion 22 exists at a depth position between the second principal surface F2 and the first principal surface F1. A width of the trench portion 22 is a width W2 smaller than the width W1 of the trench portion 21. By making the width of the trench portion 22 smaller, it is possible to reduce an etching rate at the time of etching of a semiconductor substrate in forming the trench portion 22.

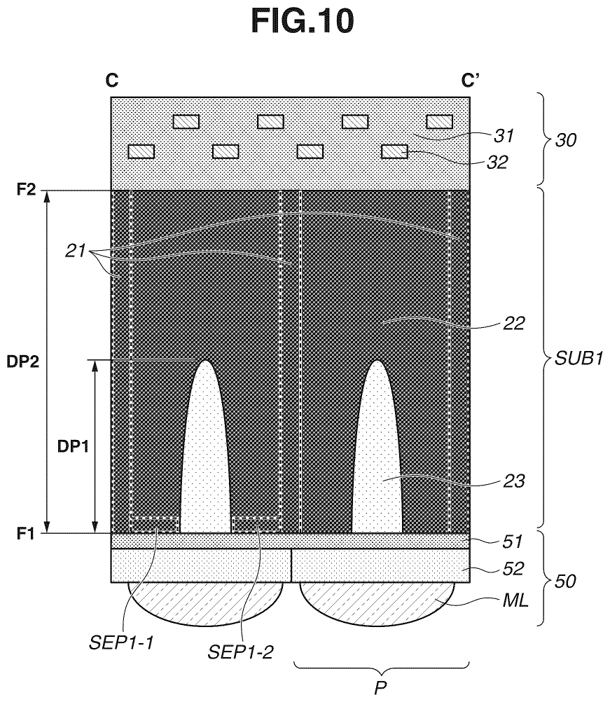

Next, FIG. 10 illustrates a cross-sectional view taken along a line C-C′ illustrated in FIG. 7. Among members illustrated in FIG. 10, the same members as the members illustrated in FIGS. 7, 8, and 9 are assigned the same reference numerals as those used in FIGS. 7, 8, and 9.

In FIG. 10, the semiconductor region 23 is formed at a position between the first portions SEP1-1 and SEP1-2 illustrated in FIG. 7. The trench portion 22 is provided between the semiconductor region 23 and the second principal surface F2.

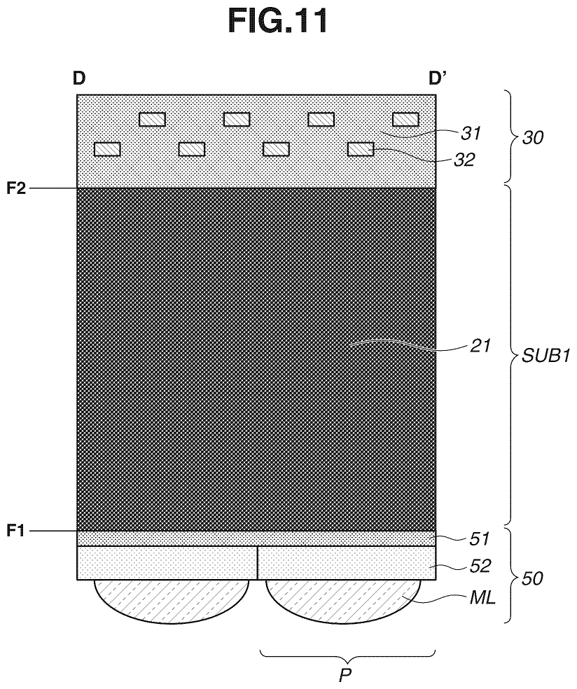

Next, FIG. 11 illustrates a cross-sectional view taken along a line D-D′ illustrated in FIG. 7. Among members illustrated in FIG. 11, the same members as the members illustrated in FIGS. 7 to 10 are assigned the same reference numerals as those used in FIGS. 7 to 10.

A length DP1 in the depth direction of the semiconductor region 23 is desirably set to ½ or less of a length DP2 between the first principal surface F1 and the second principal surface F2. For example, in a case where the length DP2 is 3 μm, it is desirable to set the length DP1 to 1.5 μm or less. With this configuration, it is possible to achieve at least one of electric separation and optical separation of the photoelectric conversion units PD1 to PD4, and the efficiency of charge movement to other photoelectric conversion units PD in a case where a part of photoelectric conversion unit PD of the photoelectric conversion units PD1 to PD4 is saturated.

In the cross-sectional view illustrated in FIG. 11, the trench portion 21 extends over a plurality of pixels P. The trench portion 21 extends from one surface to the other surface of the first principal surface F1 and the second principal surface F2 in the depth direction.

In a planar view with respect to the first principal surface F1, the structure described in the present exemplary embodiment forms the semiconductor region 23 in a region that is between the first portions SEP1-1 and SEP1-2 and between the first portions SEP2-1 and SEP2-2, the portions being a part of the trench portion 22. With this configuration, as described above, it is possible to expand a dynamic range on a high brightness side. In particular, it is possible to expand a dynamic range on a high brightness side while suppressing a deterioration in linearity of an output signal of the pixel P with respect to an incident light amount.

A second exemplary embodiment will be described mainly based on a difference from the first exemplary embodiment.

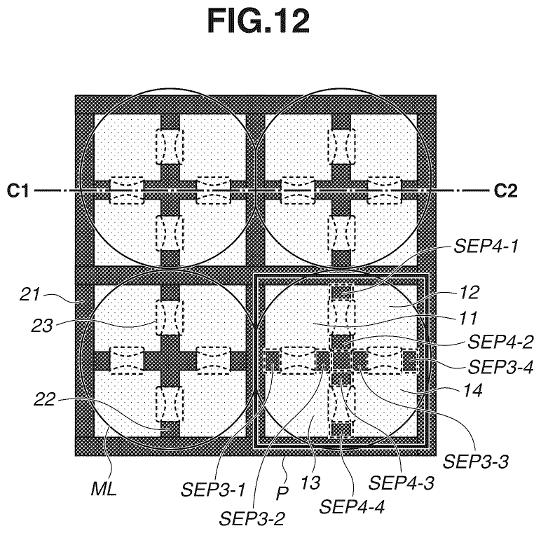

FIG. 12 is a plan view with respect to the first principal surface F1 that illustrates a photoelectric conversion apparatus according to the present exemplary embodiment. In the first exemplary embodiment, the semiconductor region 23 is provided at a position overlapping a central portion of the microlens ML in a planar view. When viewed from another perspective, in the first exemplary embodiment, one semiconductor region 23 is connected with all the semiconductor regions 11 to 14 in two rows and two columns. In the present exemplary embodiment, a plurality of semiconductor regions 23 is provided in one pixel P. In the example illustrated in FIG. 12, the semiconductor region 23 connecting two semiconductor regions of the N-type semiconductor regions 11 to 14 is provided.

The trench portion 22 includes portions SEP3-1, SEP3-2, SEP3-3, and SEP3-4 in the first direction. The trench portion 22 also includes portions SEP4-1, SEP4-2, SEP4-3, and SEP4-4 in the second direction. The semiconductor regions 23 are provided in a first region between the portions SEP3-1 and SEP3-2, in a second region between the portions SEP3-3 and SEP3-4, in a third region between portions SEP4-1 and SEP4-2, and in a fourth region between he portions SEP4-3 and SEP4-4.

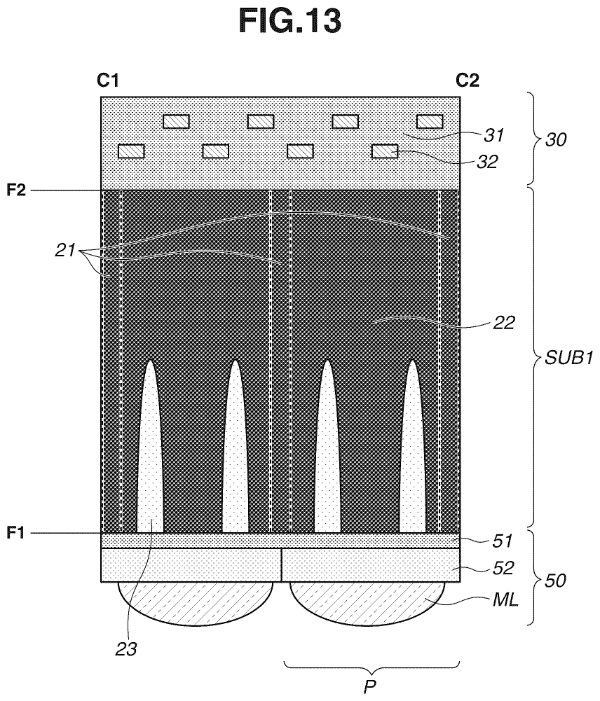

FIG. 13 illustrates a cross-sectional view taken along a line C1-C2 illustrated in FIG. 12. Among members illustrated in FIG. 13, the same members as the members illustrated in FIGS. 7 to 10 are assigned the same reference numerals as those used in FIGS. 7 to 10. As illustrated in FIG. 13, by providing a plurality of semiconductor regions 23, it is possible to improve the directionality of charges generated by a plurality of N-type semiconductor regions 11 to 14.

A third exemplary embodiment will be described mainly based on a difference from the first exemplary embodiment. In the first exemplary embodiment, the trench portions 21 and 22 are formed in a direction from the second principal surface F2 toward the first principal surface F1. In the present exemplary embodiment, trench portions 21 and 22 are formed in a direction from the first principal surface F1 toward the second principal surface F2. While the semiconductor region 23 is provided on the first principal surface F1 in the first exemplary embodiment, the semiconductor region 23 is provided on the second principal surface F2 in the present exemplary embodiment. Also in the present exemplary embodiment, photoelectric conversion units PD1 to PD4 arranged on two rows and two columns are arranged for one microlens.

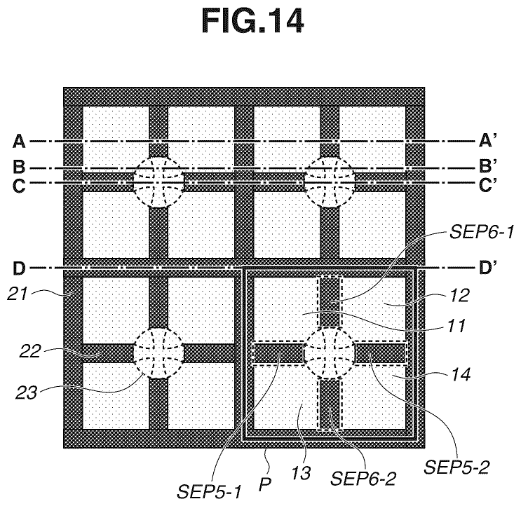

FIG. 14 is a plan view illustrating a structure of a photoelectric conversion apparatus according to the present exemplary embodiment in a planar view with respect to the second principal surface F2. Among members illustrated in FIG. 14, the same members as the members illustrated in FIG. 7 are assigned the same reference numerals as those used in FIG. 7.

On the second principal surface F2, in a planar view with respect to the second principal surface F2, the trench portion 22 includes portions SEP5-1 and SEP5-2 extending in the first direction, which is the row direction, and portions SEP6-1 and SEP6-2 extending in the second direction, which is the column direction. On the second principal surface F2, the semiconductor region 23 of the first substrate SUB1, which is a semiconductor substrate, is provided in a region that is between the portions SEP5-1 and SEP5-2, and between the second portions SEP6-1 and SEP6-2. In a planar view with respect to the second principal surface F2, a part of the trench portion 22 provided inside the first substrate SUB1 is provided at a position overlapping the semiconductor region 23. The semiconductor region 23 serves as a pathway on which charges move from one N-type semiconductor region to the other N-type semiconductor region of a plurality of N-type semiconductor regions 11 to 14. With this configuration, even in a case where a large amount of charges are generated inside a part of semiconductor regions 11 to 14 to which high-brightness light, among the plurality of N-type semiconductor regions 11 to 14, charges can be moved to the other semiconductor regions 11 to 14. With this configuration, because charges corresponding to incident light can be accumulated using a plurality of semiconductor regions 11 to 14, it is possible to expand a dynamic range on a high brightness side. In particular, it is possible to expand a dynamic range on a high brightness side while suppressing a deterioration in linearity of an output signal of the pixel P with respect to an incident light amount.

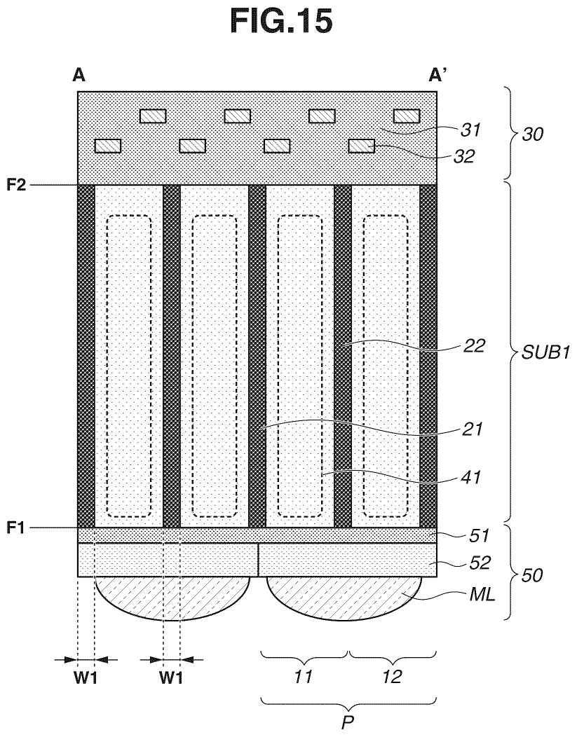

Next, FIG. 15 illustrates a cross-sectional view taken along a line A-A′ illustrated in FIG. 14.

Among members illustrated in FIG. 15, the same members as the members illustrated in FIG. 14 are assigned the same reference numerals as those used in FIG. 14.

In a cross-sectional view at a position passing through the line A-A′ illustrated in FIG. 15, the trench portion 21 and the trench portion 22 both extend from one surface to the other surface of the first principal surface F1 and the second principal surface F2 of the first substrate SUB1 in a depth direction of the first substrate SUB1. After the wiring layer 30 is formed, in a process before the optical layer 50 is formed, by performing etching processing from the first principal surface F1 toward the second principal surface F2, a hole portion is formed up to the depth of the second principal surface F2. Then, by filling this hole portion with an insulating material or a metal material, it is possible to form the trench portions 21 and 22. In the present exemplary embodiment, the trench portions 21 and the trench portion 22 have a structure of a DTI formed from the first principal surface F1 toward the second principal surface F2. In the cross section illustrated in FIG. 15, the trench portions 21 and the trench portion 22 are formed with the same width W1. In FIG. 15, the trench portions 21 and 22 both extend from the second principal surface F2 to the first principal surface F1 with the same width, but the configuration is not limited to this configuration. Both the trench portions 21 and 22 can be formed to become thinner toward the second principal surface F2.

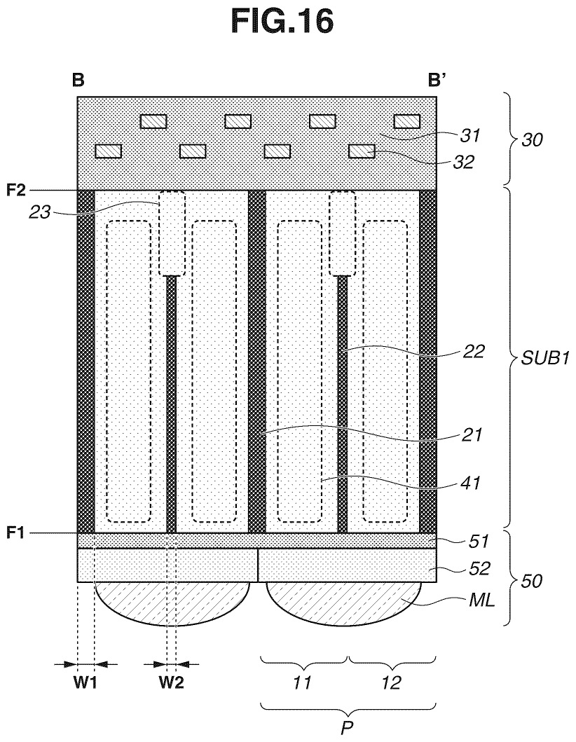

Next, FIG. 16 illustrates a cross-sectional view taken along line B-B′ illustrated in FIG. 14. Among members illustrated in FIG. 16, the same members as the members illustrated in FIGS. 14 and 15 are assigned the same reference numerals as those used in FIGS. 14 and 15.

In the cross-sectional view illustrated in FIG. 16, a bottom portion of the trench portion 22 is in contact with the semiconductor region 23. In other words, the bottom portion of the trench portion 22 exists at a depth position between the second principal surface F2 and the first principal surface F1. A width of the trench portion 22 is a width W2 smaller than the width W1 of the trench portion 21. In FIG. 16, the widths W1 and W2 are illustrated at different depth positions for the sake of illustration, but it is desirable to compare the widths W1 and W2 at the same depth position.

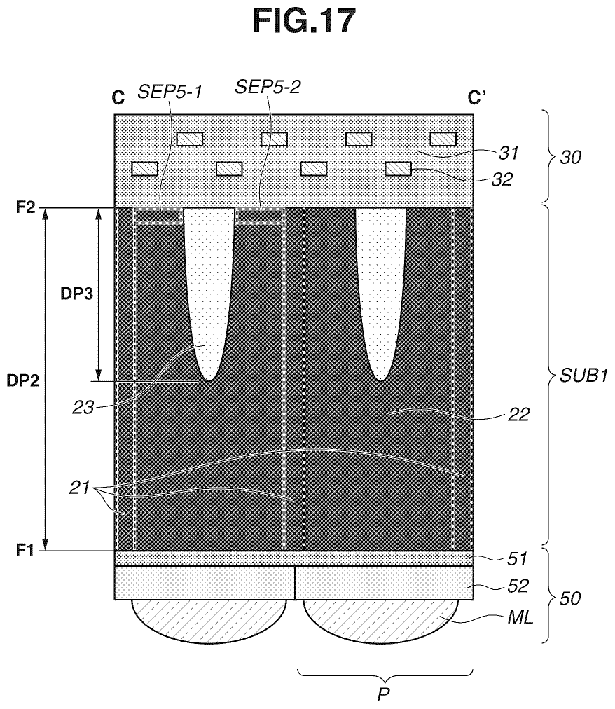

FIG. 17 illustrates a cross-sectional view taken along line C-C′ illustrated in FIG. 14. Among members illustrated in FIG. 17, the same members as the members illustrated in FIGS. 14 to 16 are assigned the same reference numerals as those used in FIGS. 14 to 16.

In FIG. 17, the semiconductor region 23 is formed at a position between the portions SEP5-1 and SEP5-2 illustrated in FIG. 14. The trench portion 22 is provided between the semiconductor region 23 and the first principal surface F1.

It is desirable to set a length DP3 in the depth direction of the semiconductor region 23 to ½ or less of the length DP2 between the first principal surface F1 and the second principal surface F2. For example, in a case where the length DP2 is 3 μm, it is desirable to set the length DP3 to 1.5 μm or less. With this configuration, it is possible to achieve at least one of electric separation and optical separation of the photoelectric conversion units PD1 to PD4, and the efficiency of charge movement to other photoelectric conversion units PD in a case where a part of photoelectric conversion unit PD of the photoelectric conversion units PD1 to PD4 is saturated.

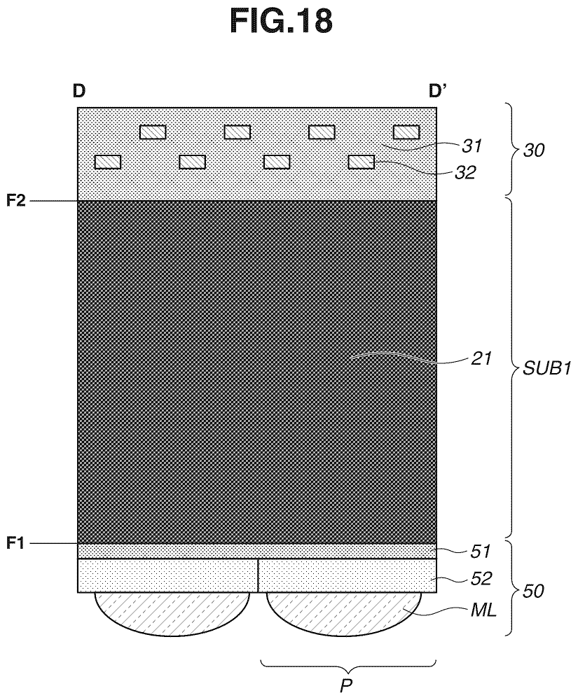

FIG. 18 illustrates a cross-sectional view taken along line D-D′ illustrated in FIG. 14. Among members illustrated in FIG. 18, the same members as the members illustrated in FIGS. 14 to 17 are assigned the same reference numerals as those used in FIGS. 14 to 17.

In the cross-sectional view illustrated in FIG. 18, the trench portion 21 extends over a plurality of pixels P. The trench portion 21 extends from one surface to the other surface of the first principal surface F1 and the second principal surface F2 in the depth direction.

In a planar view with respect to the second principal surface F2, the structure described in the present exemplary embodiment forms the semiconductor region 23 in a region that is between the portions SEP5-1 and SEP5-2 and between the portions SEP6-1 and SEP6-2, the portions being a part of the trench portion 22. With this configuration, as described above, it is possible to expand a dynamic range on a high brightness side. In particular, it is possible to expand a dynamic range on a high brightness side while suppressing a deterioration in linearity of an output signal of the pixel P with respect to an incident light amount.

A photoelectric conversion apparatus according to a fourth exemplary embodiment will be described mainly based on a difference from the third exemplary embodiment.

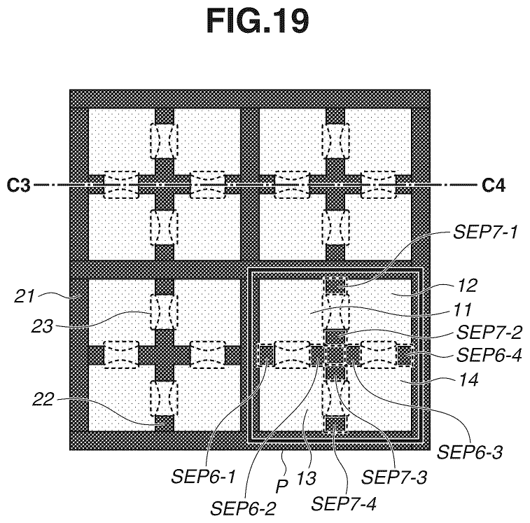

FIG. 19 is a plan view of a photoelectric conversion apparatus according to the present exemplary embodiment with respect to the second principal surface F2. In the third exemplary embodiment, one semiconductor region 23 is connected with all the semiconductor regions 11 to 14 in two rows and two columns. In the present exemplary embodiment, a plurality of semiconductor regions 23 is provided in one pixel P. In the example illustrated in FIG. 19, the semiconductor region 23 connecting two semiconductor regions of the N-type semiconductor regions 11 to 14 is provided.

The trench portion 22 includes portions SEP6-1, SEP6-2, SEP6-3, and SEP6-4 in the first direction. The trench portion 22 also includes portions SEP7-1, SEP7-2, SEP7-3, and SEP7-4 in the second direction. The semiconductor regions 23 are provided in a region between the portions SEP6-1 and the SEP6-2, in a region between the portions SEP6-3 and the SEP6-4, in a region between the portions SEP7-1 and the SEP7-2, and in region between the portions SEP7-3 and the SEP7-4.

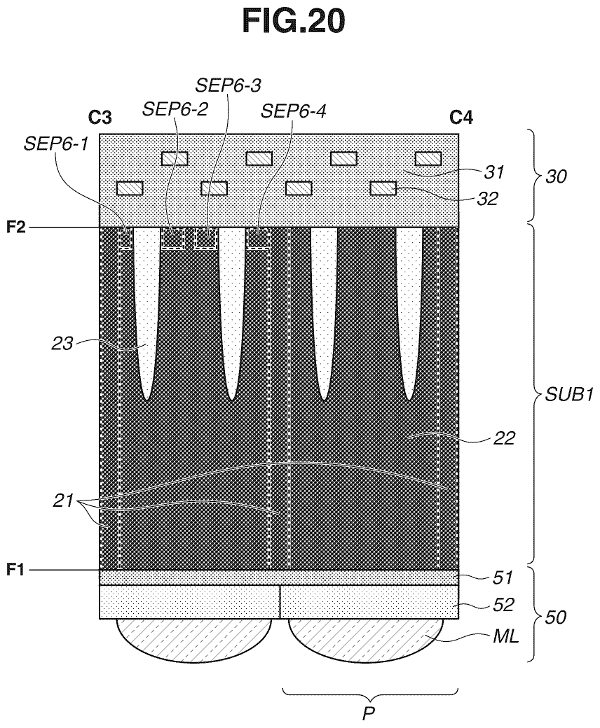

FIG. 20 illustrates a cross-sectional view taken along a line C3-C4 illustrated in FIG. 19. Among members illustrated in FIG. 20, the same members as the members illustrated in FIGS. 16 to 19 are assigned the same reference numerals as those used in FIGS. 16 to 19. As illustrated in FIG. 20, by providing a plurality of semiconductor regions 23, it is possible to improve the directionality of charges generated by a plurality of N-type semiconductor regions 11 to 14.

A photoelectric conversion apparatus according to a fifth exemplary embodiment will be described mainly based on a difference from the third exemplary embodiment.

In the photoelectric conversion apparatus according to the present exemplary embodiment, each of the trench portions 21 and 22 includes a portion extending from the first principal surface F1, and a portion extending from the second principal surface F2.

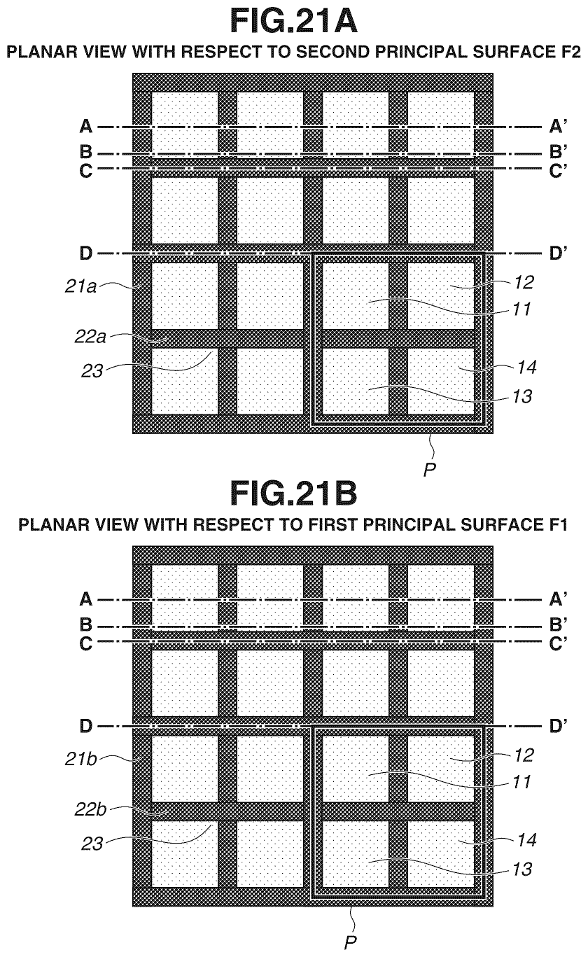

FIGS. 21A and 21B illustrate the photoelectric conversion apparatus according to the present exemplary embodiment. FIG. 21A is a plan view viewed in a planar view with respect to the second principal surface F2, and FIG. 21B is a plan view viewed in a planar view with respect to the first principal surface F1. Among members illustrated in FIGS. 21A and 21B, members having the same function as the members described in the above-described exemplary embodiments are assigned the same reference numerals as those used in the above-described exemplary embodiments. In the photoelectric conversion apparatus according to the present exemplary embodiment, a trench portion 21a is provided on the second principal surface F2 in a grid shape. A trench portion 21b is provided on the first principal surface F1 in a grid shape.

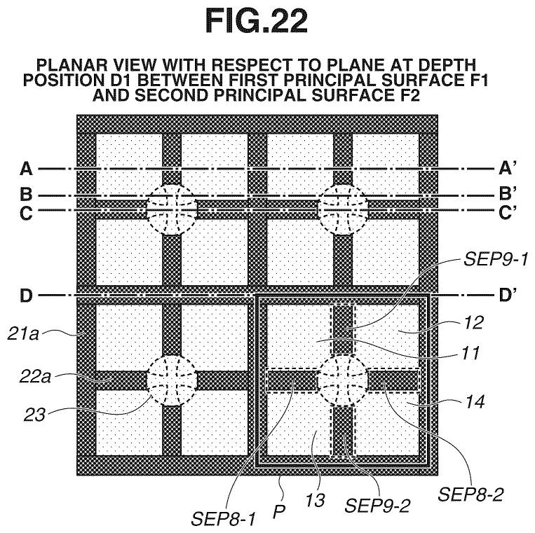

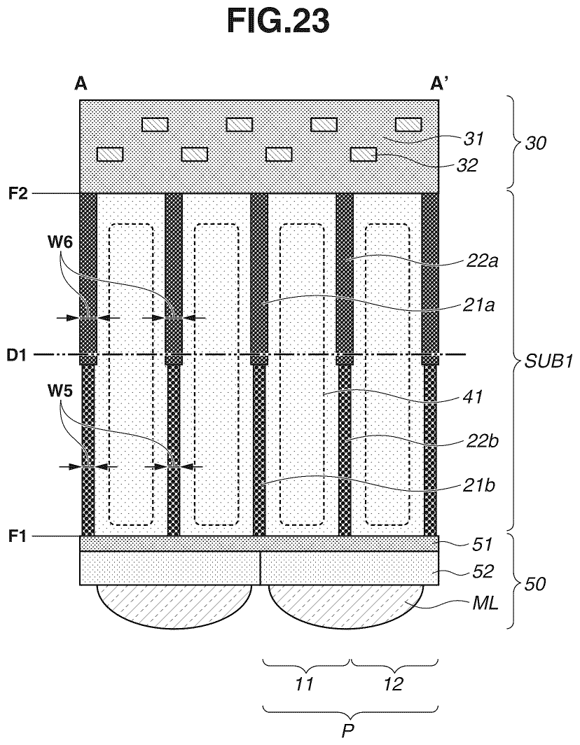

FIG. 22 is a plan view of a planar view with respect to a plane at a depth position between the second principal surface F2 and the first principal surface F1 (plane parallel to the first principal surface F1 and the second principal surface F2). The depth position is a position at a depth D1 illustrated in FIGS. 23 to 25 to be described below.

In a planar view with respect to the first principal surface, the trench portion 22a includes portions SEP8-1 and SEP8-2 extending in the first direction, which is the row direction, and portions SEP9-1 and SEP9-2 extending in the second direction, which is the column direction. On the first principal surface, the semiconductor region 23 of the first substrate SUB1, which is a semiconductor substrate, is provided in a region that is between the portions SEP8-1 and SEP8-2, and between the portions SEP9-1 and SEP9-2. In a planar view with respect to the first principal surface, a part of the trench portion 22a provided inside the first substrate SUB1 is provided at a position overlapping the semiconductor region 23. The semiconductor region 23 serves as a pathway on which charges move from one N-type semiconductor region to the other N-type semiconductor region of a plurality of N-type semiconductor regions 11 to 14. With this configuration, even in a case where a large amount of charges are generated inside partial semiconductor regions 11 to 14 to which high-brightness light enters, among the plurality of N-type semiconductor regions 11 to 14, charges can be moved to the other semiconductor regions 11 to 14. With this configuration, because charges corresponding to incident light can be accumulated using a plurality of semiconductor regions 11 to 14, it is possible to expand a dynamic range on a high brightness side. In particular, it is possible to expand a dynamic range on a high brightness side while suppressing a deterioration in linearity of an output signal of the pixel P with respect to an incident light amount.

FIG. 23 is a cross-sectional view taken along a line A-A′ illustrated in FIGS. 21A, 21B, and 22. The trench portion 21 includes the trench portion 21a extending from the second principal surface F2 toward the first principal surface F1, and the trench portion 21b extending from the first principal surface F1 toward the second principal surface F2, and the trench portion 21a and the trench portion 21b are in contact with each other inside the first substrate SUB1. Lengths by which the trench portion 21a and the trench portion 21b extend in the depth direction can be appropriately set depending on their process conditions. Typically, it is possible to set the length to a length of M/2 with respect to a length M in the depth direction from the first principal surface F1 to the second principal surface F2. FIG. 23 illustrates the trench portion 21a and the trench portion 21b in such a manner that their bottom surfaces are in contact with each other, but the configuration is not limited to this example. For example, at the time of formation of the trench portion 21b, a structural object (metal, an insulating material, polysilicon, etc.) inside the trench portion 21a may be caused to function as an etching stop, and a bottom surface of the trench portion 21b may be positioned inside the trench portion 21a. In this manner, by the trench portion 21a and the trench portion 21b being in contact with each other, it is possible to appropriately perform at least one of electric separation and optical separation between a plurality of pixels P.

The trench portion 22 includes the trench portion 22a extending from the second principal surface F2 toward the first principal surface F1, and the trench portion 22b extending from the first principal surface F1 toward the second principal surface F2. The trench portion 22a and the trench portion 22b are in contact with each other inside the first substrate SUB1. Lengths by which the trench portion 22a and the trench portion 22b extend in the depth direction can be appropriately set depending on their process conditions. Typically, it is possible to set the length to a length of M/2 with respect to the length M in the depth direction from the first principal surface F1 to the second principal surface F2. FIG. 23 illustrates the trench portion 22a and the trench portion 22b in such a manner that their bottom surfaces are in contact with each other, but the configuration is not limited to this example. For example, at the time of formation of the trench portion 22b, a structural object (metal, an insulating material, polysilicon, etc.) inside the trench portion 22a may be caused to function as an etching stop, and a bottom surface of the trench portion 22b may be positioned inside the trench portion 22a. In this manner, by the trench portion 22a and the trench portion 22b being contact with each other, it is possible to appropriately perform at least one of electric separation and optical separation between the photoelectric conversion units PD1 to PD4 included in one pixel P.

A width W6 of the trench portion 21a is wider than a width W5 of the trench portion 21b. The widths of the trench portion 21a and 22a are assumed to be the same width W6, but widths are not limited to the widths in this example, and the widths may be made different. In addition, the widths of the trench portion 21a and 22a are assumed to be the same width W5, but widths are not limited to the widths in this example, and the widths may be made different.

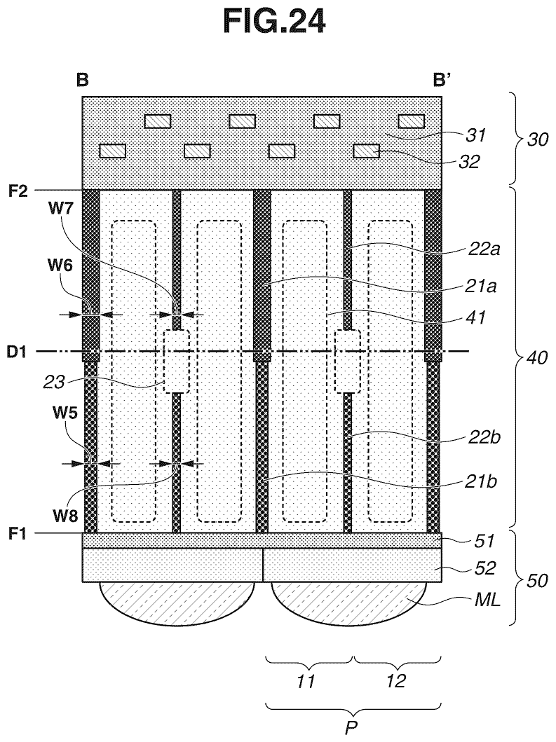

FIG. 24 is a cross-sectional view taken along a line B-B′ illustrated in FIGS. 21A, 21B, and 22. The trench portion 22a extends up to a position shallower than the depth position D1 when viewed from the second principal surface F2. The bottom surface of the trench portion 22a is in contact with the semiconductor region 23. The bottom surface of the trench portion 22b is in contact with the semiconductor region 23. In other words, the trench portion 22a and the trench portion 22b are not in contact with each other. In addition, a width W7 of the trench portion 22a is smaller than the width W6 of the trench portion 21a. In addition, a width W8 of the trench portion 22b is smaller than the width W5 of the trench portion 21b. A relationship between the widths W5 to W8 in the present exemplary embodiment is represented by the following formula.

W6>W5>W7>W8 (1)

The relationship is not limited to the relationship represented by Formula (1), and the widths W5 to W8 are only required to satisfy the relationship of W6>W7 and the relationship of W5 >W8. In other words, the relationship may be a relationship represented by any of the formulae (2) to (4).

W6=W5>W7=W8 (2)

W5>W6>W7=W8 (3)

W5>W6>W8>W7 (4)

In FIG. 24, the widths W6 and W7 are illustrated at different depth positions for the sake of illustration, but it is desirable to compare the widths W6 and W7 at the same depth position. Similarly, the widths W5 and W8 are illustrated at different depth positions for the sake of illustration, but it is desirable to compare the widths W5 and W8 at the same depth position.

As seen from the illustration in FIGS. 21A, 21B, and 24, on the first principal surface F1, in a planar view with respect to the first principal surface F1, a first trench portion 22 includes the trench portion 22b, which is a first portion extending in the first direction. In addition, on the second principal surface F2, in a planar view with respect to the second principal surface F2, the first trench portion 22 includes the trench portion 22a, which is a third portion extending in the first direction. The trench portion 22a and the trench portion 22b include portions overlapping in a planar view with respect to the first principal surface F1. The semiconductor region 23 of the first substrate SUB1 is provided between the trench portion 22a and the trench portion 22b.

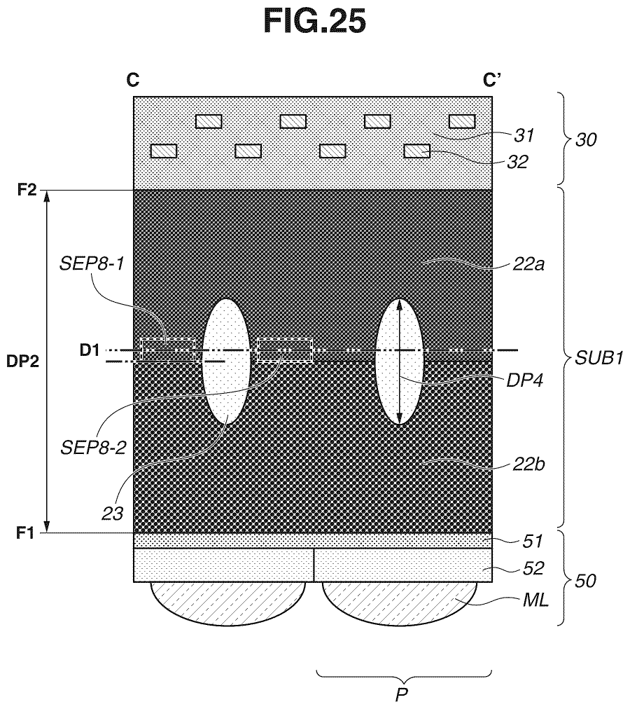

FIG. 25 is a cross-sectional view taken along a line C-C′ illustrated in FIGS. 21A, 21B, and 22. In this cross-sectional view, the semiconductor region 23 is arranged in a region surrounded by the trench portion 22a and the trench portion 22b. In addition, a portion of the semiconductor region 23 is arranged at a position between the portions SEP8-1 and SEP8-2 illustrated in FIG. 22. With this structure, it is possible to move charges to other photoelectric conversion units PD in a case where a part of photoelectric conversion unit PD of the photoelectric conversion units PD1 to PD4 is saturated.

It is desirable to set a length DP4 in the depth direction of the semiconductor region 23 to ½ or less of the length DP2 between the first principal surface F1 and the second principal surface F2. For example, in a case where the length DP2 is 3 μm, it is desirable to set the length DP4 to 1.5 μm or less. With this configuration, it is possible to achieve at least one of electric separation and optical separation of the photoelectric conversion units PD1 to PD4, and the efficiency of charge movement to other photoelectric conversion units PD in a case where a part of photoelectric conversion unit PD of the photoelectric conversion units PD1 to PD4 is saturated.

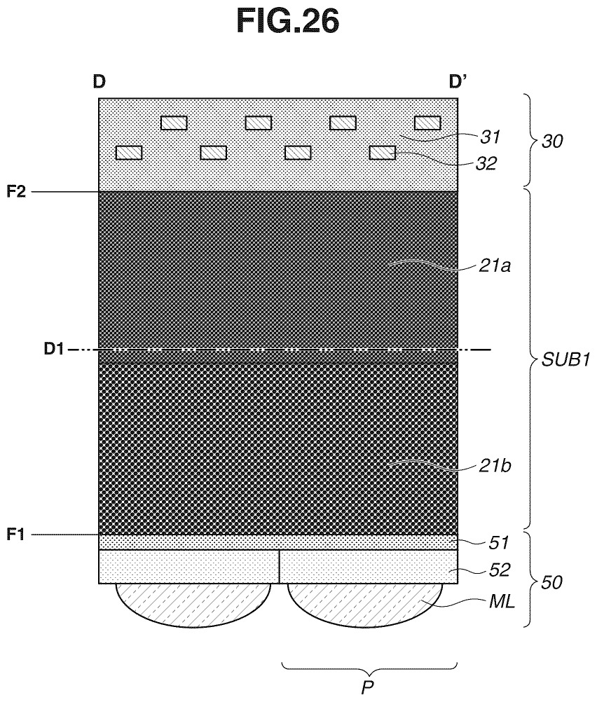

FIG. 26 is a cross-sectional view taken along a line D-D′ illustrated in FIGS. 21A, 21B, and 22. The trench portion 21a and the trench portion 21b are in contact with each other, and extend over a plurality of pixels P. With this configuration, it is possible to electrically separate photoelectric conversion units of a plurality of pixels P from each other.

Also in the present exemplary embodiment, it is possible to expand a dynamic range on a high brightness side. In particular, it is possible to expand a dynamic range on a high brightness side while suppressing a deterioration in linearity of an output signal of the pixel P with respect to an incident light amount.

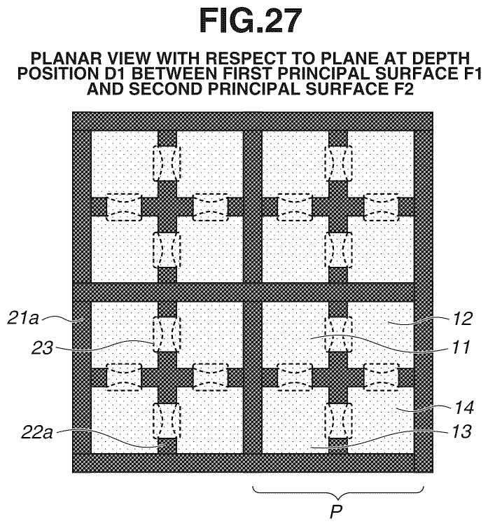

The structure in the present exemplary embodiment can be modified to the structure illustrated in FIG. 27. FIG. 27 is a plan view of a planar view with respect to the plane at the depth position D1 (plane parallel to the first principal surface F1 and the second principal surface F2).

In this modified example, a configuration is modified to a configuration in which a plurality of semiconductor regions 23 of the present exemplary embodiment is arranged as in the second exemplary embodiment and the fourth exemplary embodiment. With this configuration, it is possible to add the directionality to a moving direction of charges of the semiconductor regions 11 to 14.

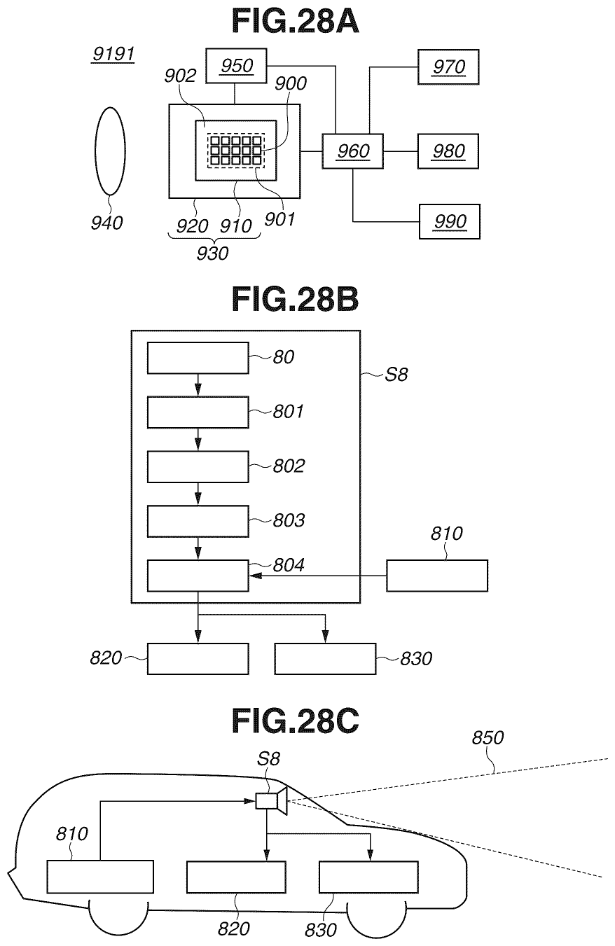

A sixth exemplary embodiment can be applied to any of the first to fifth exemplary embodiments. FIG. 28A is a schematic diagram illustrating a device 9191 including a semiconductor apparatus 930 according to the present exemplary embodiment. As the semiconductor apparatus 930, the photoelectric conversion apparatus (imaging apparatus) according to each of the above-described exemplary embodiments can be used. The device 9191 including the semiconductor apparatus 930 will be described in detail. The semiconductor apparatus 930 can include a semiconductor device 910. Aside from the semiconductor device 910, the semiconductor apparatus 930 can include a package 920 storing the semiconductor device 910. The package 920 can include a base member on which the semiconductor device 910 is fixed, and a lid member such as glass facing the semiconductor device 910. The package 920 can further include a bonding member such as a bonding wire or a bump that connects a terminal provided in the base member and a terminal provided in the semiconductor device 910.

The device 9191 can include at least any of an optical device 940, a control device 950, a processing device 960, a display device 970, a storage device 980, and a mechanical device 990. The optical device 940 corresponds to the semiconductor apparatus 930. The optical device 940 is a lens, a shutter, or a mirror, for example, and includes an optical system for guiding light to the semiconductor apparatus 930. The control device 950 controls the semiconductor apparatus 930. The control device 950 is a semiconductor apparatus such as an application specific integrated circuit (ASIC), for example.

The processing device 960 processes a signal output from the semiconductor apparatus 930. The processing device 960 is a semiconductor apparatus such as a CPU or an ASIC for forming an analog front end (AFE) or a digital front end (DFE). The display device 970 is an electroluminescent (EL) display device or a liquid crystal display device that displays information (image) obtained in the semiconductor apparatus 930. The storage device 980 is a magnetic device or a semiconductor device that stores information (image) obtained in the semiconductor apparatus 930. The storage device 980 is a volatile memory such as a static random access memory (SRAM) or a dynamic random access memory (DRAM), or a nonvolatile memory such as a flash memory or a hard disk drive.

The mechanical device 990 includes a moving unit or a propulsion unit such as a motor or an engine. In the device 9191, a signal output from the semiconductor apparatus 930 is displayed on the display device 970, and transmitted to the outside by a communication device (not illustrated) included in the device 9191. For this reason, the device 9191 desirably further includes the storage device 980 and the processing device 960 aside from a storage circuit and a calculation circuit included in the semiconductor apparatus 930. The mechanical device 990 may be controlled based on a signal output from the semiconductor apparatus 930.

The device 9191 is suitable for an electronic device such as an information terminal having an image capturing function (e.g., smartphone or wearable terminal) or a camera (e.g., interchangeable lens camera, compact camera, video camera, monitoring camera). The mechanical device 990 in a camera can drive the component of the optical device 940 for zooming, focusing, or a shutter operation. Alternatively, the mechanical device 990 in a camera can move the semiconductor apparatus 930 for an image stabilization operation.

The device 9191 can be a transport device such as a vehicle, a ship, or a flight vehicle (drone, airplane, etc.). The mechanical device 990 in a transport device can be used as a moving device. The device 9191 serving as a transport device is suitable for a device that transports the semiconductor apparatus 930, or a device that aids and/or automates driving (steering) using an image capturing function. The processing device 960 for aiding and/or automating driving (steering) can perform processing for operating the mechanical device 990 serving as a moving device, based on information obtained in the semiconductor apparatus 930. Alternatively, the device 9191 may be a medical device such as an endoscope, a measuring device such as a distance measuring sensor, an analytical device such as an electronic microscope, an office device such as a copier, or an industrial device such as a robot.

According to the above-described exemplary embodiment, it becomes possible to obtain good pixel characteristics. Accordingly, it is possible to enhance the value of the semiconductor apparatus. The enhancement of the value corresponds to at least any of the addition of a function, performance improvement, characteristic improvement, reliability improvement, manufacturing yield ratio improvement, environmental burden reduction, cost reduction, downsizing, and weight saving.

Accordingly, if the semiconductor apparatus 930 according to the present exemplary embodiment is used in the device 9191, the value of the device 9191 can also be enhanced. For example, by mounting the semiconductor apparatus 930 on a transport device, it is possible to obtain superior performance when performing the image capturing of the outside of the transport device or the measuring of an external environment. Thus, determining to mount the semiconductor apparatus according to the present exemplary embodiment on a transport device when manufacturing and selling the transport device is advantageous in improving the performance of the transport device itself. The semiconductor apparatus 930 is suitable especially for a transport device that performs drive assist and/or automatic operation of the transport device using information obtained by the semiconductor apparatus.

A photoelectric conversion system and a movable body according to the present exemplary embodiment will be described with reference to FIGS. 28B and 28C.

FIG. 28B illustrates an example of a photoelectric conversion system related to an in-vehicle camera. A photoelectric conversion system S8 includes a photoelectric conversion apparatus 80. The photoelectric conversion apparatus 80 is the photoelectric conversion apparatus (imaging apparatus) according to any of the above-described exemplary embodiments. The photoelectric conversion system S8 includes an image processing unit 801 that performs image processing on a plurality of pieces of image data acquired by the photoelectric conversion apparatus 80, and a parallax acquisition unit 802 that calculates a parallax (phase difference between parallax images) from the plurality of pieces of image data acquired by the photoelectric conversion system S8.

Here, the photoelectric conversion system S8 may include an optical system (not illustrated) such as a lens, a shutter, or a mirror, for example, that guides light to the photoelectric conversion apparatus 80. A plurality of photoelectric conversion units approximately conjugate with a pupil of the optical system may be arranged in pixels included in photoelectric conversion apparatus 80. For example, the plurality of photoelectric conversion units approximately conjugate with the pupil are arranged in such a manner as to correspond to one microlens. By the plurality of photoelectric conversion units receiving light beams having passed through mutually-different position of the pupil of the optical system, the photoelectric conversion apparatus 80 outputs image data corresponding to the light beams having passed through the different positions. Then, the parallax acquisition unit 802 may calculate a parallax using the output image data. The photoelectric conversion system S8 further includes a distance acquisition unit 803 that calculates a distance to a target object based on the calculated parallax, and a collision determination unit 804 that determines whether collision is likely to occur, based on the calculated distance. In this example, the parallax acquisition unit 802 and the distance acquisition unit 803 serve as an example of a distance information acquisition unit that acquires distance information regarding a distance to a target object. More specifically, the distance information is information regarding a parallax, a defocus amount, and a distance to a target object. The collision determination unit 804 may determine collision likelihood using any of these pieces of distance information. The distance Information may be acquired using a ToF sensor. The distance information acquisition unit may be implemented by dedicatedly-designed hardware, or may be implemented by a software module. Alternatively, the distance information acquisition unit may be implemented by a field programmable gate array (FPGA) or an application specific integrated circuit (ASIC), or may be implemented by the combination of these. The photoelectric conversion system S8 is connected with a vehicle information acquisition apparatus 810, and can acquire vehicle information such as a vehicle speed, a yaw rate, or a rudder angle. In addition, an electronic control unit (ECU) 820 is connected to the photoelectric conversion system S8. The ECU 820 serves as a control apparatus that outputs a control signal for generating braking force, to a vehicle based on a determination result obtained by the collision determination unit 804. The photoelectric conversion system S8 is also connected with an alarm apparatus 830 that raises an alarm to a driver based on a determination result obtained by the collision determination unit 804. For example, in a case where the determination result obtained by the collision determination unit 804 indicates high collision likelihood, the ECU 820 performs vehicle control for avoiding collision or reducing damages by braking, releasing an accelerator, or suppressing engine output. The alarm apparatus 830 issues an alarm to a user by sounding an alarm, displaying warning information on a screen of a car navigation system, or vibrating a seatbelt or a steering wheel.

In the present exemplary embodiment, the photoelectric conversion system S8 captures an image of the periphery of the vehicle such as the front side or the rear side, for example. FIG. 28C illustrates the photoelectric conversion system S8 for capturing an image of a vehicle front side (imaging range 850). The vehicle information acquisition apparatus 810 issues an instruction to the photoelectric conversion system S8 or the imaging apparatus 80. With this configuration, the accuracy of distance measurement can be further enhanced.

The above description has been given of an example in which control is performed in such a manner as not to collide with another vehicle. The photoelectric conversion system can also be applied to the control for performing automatic operation by following another vehicle, or the control for performing automatic operation in such a manner as not to deviate from a lane. Furthermore, the photoelectric conversion system S8 can be applied to a movable body (moving apparatus) such as a vessel, an aircraft, or an industrial robot, for example, aside from a vehicle such as an automobile. This movable body includes either one or both of a drive force generation unit that generates drive force to be mainly used for the movement of the movable body, and a rotator to be mainly used for the movement of the movable body. The drive force generation unit can be an engine, a motor, or the like. The rotator can be a tire, a wheel, a screw of a ship, a propeller of a flight vehicle, or the like. Moreover, the photoelectric conversion system can be applied to a device that extensively uses object recognition, such as an intelligent transport system (ITS), in addition to a movable body. [Modified Exemplary Embodiment]

The present invention is not limited to the above-described exemplary embodiments, and various modifications can be made.

For example, an example in which a partial configuration of a certain exemplary embodiment is added to another exemplary embodiment, and an example in which a partial configuration of a certain exemplary embodiment is replaced with a partial configuration of another exemplary embodiment are also included in the exemplary embodiments of the present invention.

The device and the photoelectric conversion systems described in the above-described sixth exemplary embodiment are examples of the photoelectric conversion systems to which the photoelectric conversion apparatus can be applied, and the photoelectric conversion system to which the photoelectric conversion apparatus of the present invention can be applied is not limited to the configuration illustrated in FIGS. 13 and 14.

The above-described exemplary embodiments merely indicate examples of substantiation in executing the present invention, and the technical scope of the prevent invention is not to be construed in a limited manner based on these embodiments. That is, the present invention can be executed in various forms without departing from the technical idea or major features thereof.

In this specification, the wordings such as “A or B”, “at least one of A and B”, “at least one of A or/and B”, and “one or more of A or/and B” can include all possible combinations of listed items, unless otherwise explicitly defined. That is, the above-described wordings are interpreted as disclosing all cases of a case where at least one A is included, a case where at least one B is included, and a case where both of at least one A and at least one B are included. The same applies to the combination of three or more components.

The exemplary embodiments described above can be appropriately changed without departing from the technical idea. The disclosure in this specification is not limited to matters described in this specification, and includes all matters that can be identified from this specification and the drawings accompanying this specification. The disclosure in this specification includes a complementary set of individual concepts described in this specification. More specifically, if “A is larger than B” is described in this specification, even if the description “B is not larger than A” is omitted, this specification is assumed to disclose that “B is not larger than A”. This is because, in a case where “A is larger than B” is described, a case where “B is not larger than A” is assumed to be considered.

According to the technique of the present disclosure, it is possible to provide a desirable structure of a trench portion in a configuration in which a plurality of photoelectric conversion units is provided for one microlens.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-021764, filed Feb. 16, 2024, which is hereby incorporated by reference herein in its entirety.

What is claimed is:

1. A photoelectric conversion apparatus comprising:
a semiconductor substrate having a first principal surface from which light enters, and a second principal surface facing the first principal surface;
a microlens array including a plurality of microlenses;
a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, and a first trench portion that separates the plurality of photoelectric conversion units; and
a second trench portion provided between a photoelectric conversion unit included in one pixel of neighboring two pixels among the plurality of pixels, and a photoelectric conversion unit included in other one pixel of the neighboring two pixels, wherein, on the first principal surface, in a planar view with respect to the first principal surface, the first trench portion includes a plurality of first portions extending in a first direction, and a plurality of second portions extending in a second direction intersecting with the first direction,
wherein a first region between one first portion and other first portion of the plurality of first portions, and a second region between one second portion and other second portion of the plurality of second portions each include a semiconductor region of the semiconductor substrate, and
wherein, at a depth position between the first principal surface and the second principal surface, in the planar view, a part of the first trench portion is arranged at each of a position overlapping the first region and a position overlapping the second region.

2. A photoelectric conversion apparatus comprising:
a semiconductor substrate having a first principal surface from which light enters, and a second principal surface facing the first principal surface;
a microlens array including a plurality of microlenses;
a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, a first trench portion that separates the plurality of photoelectric conversion units, and a plurality of amplification transistors each having a gate; and
a second trench portion provided between a photoelectric conversion unit included in one pixel of neighboring two pixels among the plurality of pixels, and a photoelectric conversion unit included in other one pixel of the neighboring two pixels,
wherein the respective gates of the plurality of amplification transistors are connected in common to a node to which signal charges of the plurality of photoelectric conversion units are input,
wherein, on the second principal surface, in a planar view with respect to the second principal surface, the first trench portion includes a plurality of first portions extending in a first direction, and a plurality of second portions extending in a second direction intersecting with the first direction,
wherein a first region between one first portion and other first portion of the plurality of first portions, and a second region between one second portion and other second portion of the plurality of second portions each include a semiconductor region of the semiconductor substrate, and
wherein, at a depth position between the first principal surface and the second principal surface, in the planar view, a part of the first trench portion is arranged at each of a position overlapping the first region and a position overlapping the second region.

3. A photoelectric conversion apparatus comprising:
a semiconductor substrate having a first principal surface from which light enters, and a second principal surface facing the first principal surface;
a microlens array including a plurality of microlenses;
a plurality of pixels each including a corresponding one microlens of the plurality of microlenses, a plurality of photoelectric conversion units in a plurality of rows and a plurality of columns that is arranged inside the semiconductor substrate, and arranged in such a manner as to corresponding to the one microlens, and a first trench portion that separates the plurality of photoelectric conversion units; and
a second trench portion provided between a photoelectric conversion unit included in one pixel of neighboring two pixels among the plurality of pixels, and a photoelectric conversion unit included in other one pixel of the neighboring two pixels,
wherein, on the first principal surface, in a planar view with respect to the first principal surface, the first trench portion includes a first portion extending in a first direction,
wherein, on the second principal surface, in a planar view with respect to the second principal surface, the first trench portion includes a third portion extending in the first direction,
wherein the first portion and the third portion have portions overlapping in the planar view with respect to the first principal surface, and
wherein a semiconductor region of the semiconductor substrate is arranged between the first portion and the third portion.

4. The photoelectric conversion apparatus according to claim 1,
wherein each of the plurality of pixels includes a plurality of amplification transistors, and
wherein the respective gates of the plurality of amplification transistors are connected in common to a node to which signal charges of the plurality of photoelectric conversion units are input.

5. The photoelectric conversion apparatus according to claim 3,
wherein each of the plurality of pixels includes a plurality of amplification transistors, and
wherein the respective gates of the plurality of amplification transistors are connected in common to a node to which signal charges of the plurality of photoelectric conversion units are input.

6. The photoelectric conversion apparatus according to claim 1, wherein the semiconductor region included in each of the first region and the second region extends from the first principal surface up to a predetermined portion positioned at a predetermined depth of the semiconductor substrate, and the first trench portion extends from the predetermined portion up to the second principal surface.

7. The photoelectric conversion apparatus according to claim 2, wherein the semiconductor region included in each of the first region and the second region extends from the second principal surface up to a predetermined portion positioned at a predetermined depth of the semiconductor substrate, and the first trench portion extends from the predetermined portion up to the first principal surface.

8. The photoelectric conversion apparatus according to claim 3, wherein the semiconductor region of the semiconductor substrate is positioned on the semiconductor substrate at a predetermined depth from the first principal surface, and the first trench portion is arranged between the semiconductor region and the first principal surface, and between the semiconductor region and the second principal surface.

9. The photoelectric conversion apparatus according to claim 1,
wherein a part of the first trench portion is arranged between one photoelectric conversion unit of photoelectric conversion units in the plurality of rows, and a different photoelectric conversion unit of photoelectric conversion units in the plurality of rows, and
wherein a part of the first trench portion is arranged between one photoelectric conversion unit of photoelectric conversion units in the plurality of columns and a different photoelectric conversion unit of photoelectric conversion units in the plurality of columns.

10. The photoelectric conversion apparatus according to claim 2,
wherein a part of the first trench portion is arranged between one photoelectric conversion unit of photoelectric conversion units in the plurality of rows, and a different photoelectric conversion unit of photoelectric conversion units in the plurality of rows, and
wherein a part of the first trench portion is arranged between one photoelectric conversion unit of photoelectric conversion units in the plurality of columns and a different photoelectric conversion unit of photoelectric conversion units in the plurality of columns.

11. The photoelectric conversion apparatus according to claim 3,
wherein a part of the first trench portion is arranged between one photoelectric conversion unit of photoelectric conversion units in the plurality of rows and a different photoelectric conversion unit of photoelectric conversion units in the plurality of rows, and
wherein a part of the first trench portion is arranged between one photoelectric conversion unit of photoelectric conversion units in the plurality of columns and a different photoelectric conversion unit of photoelectric conversion units in the plurality of columns.

12. The photoelectric conversion apparatus according to claim 3,
wherein the semiconductor region is arranged between one photoelectric conversion unit of photoelectric conversion units in the plurality of rows and a different photoelectric conversion unit of photoelectric conversion units in the plurality of rows,
wherein, on the first principal surface, in a planar view with respect to the first principal surface, the first trench portion includes a fourth portion extending in a second direction,
wherein, on the second principal surface, in a planar view with respect to the second principal surface, the first trench portion includes a fifth portion extending in the second direction,
wherein the fourth portion and the fifth portion include portions overlapping in the planar view with respect to the first principal surface, and a second semiconductor region of the semiconductor substrate is arranged between the fourth portion and the fifth portion, and
wherein the second semiconductor region is arranged between one photoelectric conversion unit of photoelectric conversion units in the plurality of columns and a different photoelectric conversion unit of photoelectric conversion units in the plurality of columns.

13. The photoelectric conversion apparatus according to claim 12,
wherein the semiconductor region is arranged between one photoelectric conversion unit of photoelectric conversion units in the plurality of rows and a different photoelectric conversion unit of photoelectric conversion units in the plurality of rows,
wherein, on the first principal surface, in a planar view with respect to the first principal surface, the first trench portion includes a fourth portion extending in a second direction,
wherein, on the second principal surface, in a planar view with respect to the second principal surface, the first trench portion includes a fifth portion extending in the second direction,
wherein the fourth portion and the fifth portion include portions overlapping in the planar view with respect to the first principal surface, and a second semiconductor region of the semiconductor substrate is arranged between the fourth portion and the fifth portion, and
wherein the second semiconductor region is arranged between one photoelectric conversion unit of photoelectric conversion units in the plurality of columns and a different photoelectric conversion unit of photoelectric conversion units in the plurality of columns.

14. A device comprising:
the semiconductor apparatus according to claim 1,
wherein the device further includes at least any one of:
an optical device adapted to the semiconductor apparatus,
a control device configured to control the semiconductor apparatus,
a processing device configured to process a signal output from the semiconductor apparatus,
a display device configured to display information obtained by the semiconductor apparatus,
a storage device configured to store information obtained by the semiconductor apparatus, and
a mechanical device configured to operate based on information obtained by the semiconductor apparatus.

15. A device comprising:
the semiconductor apparatus according to claim 2,
wherein the device further includes at least any one of:
an optical device adapted to the semiconductor apparatus,
a control device configured to control the semiconductor apparatus,
a processing device configured to process a signal output from the semiconductor apparatus,
a display device configured to display information obtained by the semiconductor apparatus,
a storage device configured to store information obtained by the semiconductor apparatus, and
a mechanical device configured to operate based on information obtained by the semiconductor apparatus.

16. A device comprising:
the semiconductor apparatus according to claim 3,
wherein the device further includes at least any one of:
an optical device adapted to the semiconductor apparatus,
a control device configured to control the semiconductor apparatus,
a processing device configured to process a signal output from the semiconductor apparatus,
a display device configured to display information obtained by the semiconductor apparatus,
a storage device configured to store information obtained by the semiconductor apparatus, and
a mechanical device configured to operate based on information obtained by the semiconductor apparatus.
